(19) United States
(12) Patent Application Publication
(10) Pub. No.: US 2026/0075709 A1
(43) Pub. Date: Mar. 12, 2026

(54) ELECTRONIC DEVICE AND MANUFACTURING METHOD THEREOF

(71) Applicant: PanelSemi Corporation, New Taipei City (TW)

(72) Inventor: Chin-Tang LI, New Taipei City (TW)

(21) Appl. No.: 19/327,443

(22) Filed: Sep. 12, 2025

Related U.S. Application Data
(60) Provisional application No. 63/693,851, filed on Sep. 12, 2024.

(51) Int. Cl. H05K 1/03; H05K 1/11

(52) U.S. Cl. CPC H05K 1/0306; H05K 1/115; H05K 2201/068

(57) ABSTRACT

An electronic device includes a core substrate, a conductive layer structure, an adhesive pattern layer, and a conductive member. The core substrate defines two opposite surfaces and has a through hole penetrating the two surfaces. The conductive layer structure is stacked over one side of the core substrate, at least partially covering one opening of the through hole. The adhesive pattern layer is disposed between the conductive layer structure and the core substrate, bonding the conductive layer structure to the core substrate; the adhesive pattern layer has an opening window exposing at least a portion of the conductive layer structure; the through hole and the opening window at least partially overlap in the projection direction. The conductive member is formed from a thermally cured conductive material, disposed in the through hole of the core substrate, with one end electrically connected to the conductive layer structure through the opening window.

### CROSS REFERENCE TO RELATED APPLICATIONS

This Non-provisional application claims priority to U.S. provisional patent application with Ser. No. 63/693,851 filed on Sep. 12, 2024. This and all other extrinsic materials discussed herein are incorporated by reference in their entirety.

### BACKGROUND

### Technology Field

The disclosure relates to an electronic device provided with core substrate function.

### Description of Related Art

With the continuous development of electronic technology, the integration and functional density of electronic devices are constantly increasing. To achieve higher performance and smaller sizes, it is necessary to realize more interconnections and functions within limited space. The traditional planar integration approach is already struggling to meet the ever-growing demands. Therefore, developing an electronic device structure and manufacturing method, that can achieve high integration and vertical interconnection, is of great significance.

### SUMMARY

One or more exemplary embodiments of this disclosure are to provide an electronic device describing with a through hole and a patterned conductive layer, as well as its manufacturing method, to achieve high integration and vertical interconnection, thereby enhancing the performance and functional density of the electronic device.

One or more exemplary embodiments of this disclosure are to provide an electronic device. The electronic device includes a core substrate, a conductive layer structure, an adhesive pattern layer, and a conductive member. The core substrate defines two surfaces opposed to each other and being provided with a through hole penetrating the two surfaces thereof, wherein a projection direction is defined as a direction perpendicular to at least one of the two surfaces of the core substrate. The conductive layer structure is stacking over one side of the core substrate; wherein the conductive pattern-layered structure at least partially covers of one opening the through hole. The adhesive pattern layer is locating between the conductive layer structure and the core substrate, and bonding the conductive layer structure to the core substrate; the adhesive pattern layer has an opening window that exposes at least a part of the conductive layer structure; wherein the through hole and the opening window overlap at least partially in the projection direction. The conductive member, having thermally cured conductive material, is setting in the through hole of the core substrate, with one end electrically connected to the conductive layer structure through the opening window.

In one embodiment of the electronic device, the core substrate is made of one or more inorganic material(s).

In one embodiment of the electronic device, the core substrate includes at least one of glass, ceramic, and glass-ceramic material.

In one embodiment of the electronic device, the core substrate defines a thermal expansion coefficient no greater than 30 ppm/° C. and no less than 17 ppm/° C.

In one embodiment of the electronic device, the core substrate is a single substrate.

In one embodiment of the electronic device, the conductive layer structure includes a conductive structure, and the conductive structure includes a single layer or multiple layers of conductive layers.

In one embodiment of the electronic device, the single layer conductive layer is an undefined conductive layer.

In one embodiment of the electronic device, the single layer or multiple layers is(are) patterned conductive layer(s), and the conductive structure further includes an insulating layer interwoven and combined with the conductive layer or layers.

In one embodiment of the electronic device, the multiple conductive layers are stacked in the projection direction, and at least two of the conductive layers are electrically connected to each other.

In one embodiment of the electronic device, the conductive layer structure includes one material or any combination of conductive materials including aluminum and copper.

In one embodiment of the electronic device, the conductive layer structure further includes a base layer attached to the conductive structure; the base layer and the core substrate are located on opposite sides of the conductive structure.

In one embodiment of the electronic device, the conductive layer structure further has an external linking hole exposing at least a part of the conductive layer or the corresponding one of the conductive layers; the external linking hole includes at least a through via in the insulating layer.

In one embodiment of the electronic device, the conductive layer structure further has an external linking hole exposing at least a part of the conductive layer or the corresponding one of the conductive layers; the external linking hole includes a through via in the insulating layer and further includes a via in the base layer.

In one embodiment of the electronic device, the insulating layer includes one or any combination of Polyimide (PI), Silicon Nitride, Silicon oxides, Alumina, Aluminum Nitride, Silicon Carbide, Magnesia, Titania, Lead Zirconate Titanate (PZT), and epoxy resin materials.

In one embodiment of the electronic device, the base layer includes Polyimide (PI) material.

In one embodiment of the electronic device, the conductive layer structure further includes an external conductive structure, set in the external linking hole and electrically connected to the corresponding conductive layer.

In one embodiment of the electronic device, the external conductive structure further has a surface treatment layer set on the conductive layer or the corresponding one of the conductive layers.

In one embodiment of the electronic device, the surface treatment layer includes one material or any combination of conductive materials including copper, nickel, gold, silver, chromium, titanium, tungsten, and tin.

In one embodiment of the electronic device, the external conductive structure further has an external conductive member set and electrically connected to the conductive layer or the corresponding one of the conductive layers.

In one embodiment of the electronic device, the external conductive structure further has an external conductive member set and electrically connected to the surface treatment layer.

In one embodiment of the electronic device, the conductive member includes one material or any combination of conductive materials including copper, silver, tin, and bismuth.

In one embodiment of the electronic device, the conductive member includes one or more conductive materials, wherein the volume of these conductive materials is not less than 70% of the volume of the through hole.

In one embodiment of the electronic device, the conductive member includes resin material.

In one embodiment of the electronic device, the number of through holes and conductive members is multiple, with each conductive member corresponding to one of the through holes.

In one embodiment of the electronic device, the conductive member extends into the conductive layer structure.

In one embodiment of the electronic device, the adhesive pattern layer includes organic materials.

In one embodiment of the electronic device, the adhesive pattern layer includes metal compounds or metal transitional materials.

In one embodiment of the electronic device, the conductive member at least partially contacts the adhesive pattern layer.

In one embodiment of the electronic device, the conductive member has a conductive core and a conductive interlayer; the conductive core is located in the through hole, the conductive interlayer electrically connects the conductive core and the conductive layer structure; the conductive interlayer extends along the surface of the core substrate corresponding to the conductive layer structure, and is located in the opening window of the adhesive pattern layer.

In one embodiment of the electronic device, the conductive core and the conductive interlayer are made of the same material.

In one embodiment of the electronic device, the conductive layer structure further includes a surface treatment layer located in the opening window and electrically connected to the conductive layer structure.

In one embodiment of the electronic device, the surface treatment layer includes one material or any combination of conductive materials including copper, nickel, gold, silver, chromium, titanium, tungsten, and tin.

In one embodiment of the electronic device, the other end of the conductive member protrudes from the other side of the core substrate.

In one embodiment of the electronic device, the electronic device further includes an external conductive layer, set on the other side of the core substrate, electrically connected to the other end of the conductive member.

In one embodiment of the electronic device, the external conductive layer at least partially covers the other end of the conductive member.

In one embodiment of the electronic device, the external conductive layer includes one material or any combination of conductive materials including copper, silver, nickel, gold, tin, and bismuth.

In one embodiment of the electronic device, the electronic device further includes: an associate conductive layer structure stacking over the other side of the core substrate; and an associate adhesive pattern layer, locating between the associate conductive layer structure and the core substrate, and bonding thereto; wherein the associate adhesive pattern layer has an opening window that exposes at least a part of the conductive layer structure; wherein the through hole and the opening window at least partially overlap in the projection direction; wherein the other end of the conductive member electrically connects to the associate conductive layer structure through the opening window of the associate adhesive pattern layer.

In one embodiment of the electronic device, the associate conductive layer structure and the through hole at least partially overlap in the projection direction.

In one embodiment of the electronic device, the associate conductive layer structure includes a conductive structure including a single or multiple of conductive layers.

In one embodiment of the electronic device, the single layer conductive layer is an undefined conductive layer.

In one embodiment of the electronic device, the single layer or multiple layers of conductive layers are patterned conductive layers, and the conductive structure further includes an insulating layer interwoven with the conductive layer(s).

In one embodiment of the electronic device, the multiple conductive layers are stacked in the projection direction, and at least two of the conductive layers are electrically connected to each other.

In one embodiment of the electronic device, the associate conductive layer structure includes one or any combination of conductive materials including aluminum and copper.

In one embodiment of the electronic device, the associate conductive layer structure further includes a base layer attached to the conductive structure; the base layer and the core substrate are located on opposite sides of the associate conductive layer structure.

In one embodiment of the electronic device, the associate conductive layer structure further has an external linking hole; the external linking hole includes at least an opening in the insulating layer, exposing at least a part of the conductive layer or one of the conductive layers.

In one embodiment of the electronic device, the associate conductive layer structure further has an external linking hole; the external linking hole includes a through-via in the insulating layer and further includes a via in the base layer, exposing at least a part of the conductive layer or one of the conductive layers.

In one embodiment of the electronic device, the insulating layer includes polyimide, Silicon Nitride, Silicon oxides, Alumina, Aluminum Nitride, Silicon Carbide, Magnesia, Titania, Lead Zirconate Titanate (PZT), epoxy resin materials, or any combination thereof.

In one embodiment of the electronic device, the base layer includes polyimide material.

In one embodiment of the electronic device, the conductive layer structure further includes an external conductive structure, set in the external linking hole, electrically connected to the corresponding conductive layer.

In one embodiment of the electronic device, the external conductive structure further has a surface treatment layer set on the corresponding conductive layer.

In one embodiment of the electronic device, the surface treatment layer includes one material or any combination of conductive materials including copper, nickel, gold, silver, chromium, titanium, tungsten, and tin.

In one embodiment of the electronic device, the external conductive structure further has an external conductive member set and electrically connected to the corresponding conductive layer.

In one embodiment of the electronic device, the external conductive structure further has an external conductive member set and electrically connected to the surface treatment layer.

In one embodiment of the electronic device, the conductive member extends into the associate conductive layer structure.

In one embodiment of the electronic device, the associate adhesive pattern layer includes organic materials.

In one embodiment of the electronic device, the associate adhesive pattern layer includes metal compounds or metal transitional materials.

In one embodiment of the electronic device, the conductive member at least partially contacts the associate adhesive pattern layer.

In one embodiment of the electronic device, the conductive member has a conductive core and two conductive interlayers connecting both ends of the conductive core; the conductive core is located in the through hole, one of the conductive interlayers electrically connects one end of the conductive core to the conductive layer structure, the other conductive interlayer electrically connects the other end of the conductive core to the associate conductive layer structure; one of the conductive interlayers extends along the surface of the core substrate corresponding to the conductive layer structure and is located in the opening window of the adhesive pattern layer; the other conductive interlayer extends along the other surface of the core substrate corresponding to the associate conductive layer structure and is located in the opening window of the associate adhesive pattern layer.

In one embodiment of the electronic device, the conductive core and the two conductive interlayers are made of the same material.

In one embodiment of the electronic device, the associate conductive layer structure further includes a surface treatment layer located in the opening window.

In one embodiment of the electronic device, the surface treatment layer includes one or any combination of conductive materials including copper, nickel, gold, silver, chromium, titanium, tungsten, and tin.

One or more exemplary embodiments of this disclosure are to provide a manufacturing method of an electronic device. The manufacturing method includes steps below:
forming a single-sided structure assembly; wherein the single-sided structure assembly includes: a core substrate, having a through hole penetrating two surfaces thereof; defining a projection direction perpendicular to one surface of the core substrate; a conductive layer structure, stacking over one side of the core substrate, and covering at least a part of the through hole; and an adhesive pattern layer, locating between the conductive layer structure and the core substrate, and bonding the conductive layer structure and the core substrate; wherein the adhesive pattern layer has an opening window, the opening window exposes at least a part of the conductive layer structure; wherein the through hole and the opening window at least partially overlap in the projection direction; and
arranging a conductive member in the single-sided structure assembly and further including:
arranging a conductive material in the through hole of the core substrate; and
providing a thermal curing process to the conductive material to form the conductive member; wherein one end of the conductive member is electrically connected to the conductive layer structure through the opening window.

In one embodiment of the manufacturing method of the electronic device, the step of arranging the conductive member includes: printing, spraying, or placing a conductive material into the through hole; wherein the conductive material includes conductive adhesive; and providing a thermal curing process to the conductive material to form the conductive member.

In one embodiment of the manufacturing method of the electronic device, the conductive member includes one of, or any combination of, conductive materials including copper, silver, tin, and bismuth.

In one embodiment of the manufacturing method of the electronic device, the conductive member includes one or more conductive materials, wherein the volume of these conductive materials is not less than 70% of the volume of the through hole.

In one embodiment of the manufacturing method of the electronic device, the conductive member includes resin material.

In one embodiment of the manufacturing method of the electronic device, there are multiple through holes and conductive members, each conductive member corresponding to one of the through holes.

In one embodiment of the manufacturing method of the electronic device, the conductive member extends into the conductive layer structure.

In one embodiment of the manufacturing method of the electronic device, the core substrate is made of inorganic materials.

In one embodiment of the manufacturing method of the electronic device, the core substrate includes at least one of glass, ceramic, and glass-ceramic materials.

In one embodiment of the manufacturing method of the electronic device, the coefficient of thermal expansion of the core substrate is not greater than 30 ppm/° C. and not less than 17 ppm/° C.

In one embodiment of the manufacturing method of the electronic device, the core substrate is a single substrate.

In one embodiment of the manufacturing method of the electronic device, the step of forming the single-sided structure assembly includes: preparing an undefined initial substrate; stacking an adhesive structure onto the initial substrate; wherein the adhesive structure includes an undefined adhesive layer and a release layer; the undefined adhesive layer is located between the release layer and the initial substrate; performing a through hole process on the initial substrate and the adhesive structure bonded thereto; wherein the initial substrate defines the through hole to form the core substrate, and the adhesive structure defines the opening window to form the adhesive pattern layer; removing the release layer; and attaching a conductive layer structure to the adhesive pattern layer bonded to the core substrate.

In one embodiment of the manufacturing method of the electronic device, the step of forming the single-sided structure assembly includes: preparing the core substrate; laying the adhesive pattern layer onto the core substrate; and attaching the conductive layer structure to the adhesive pattern layer bonded to the core substrate.

In one embodiment of the manufacturing method of the electronic device, in the step of forming the single-sided structure assembly, wherein the step of arranging the conductive layer structure includes the steps of: preparing the conductive layer structure; wherein the conductive layer structure includes a conductive structure and a base layer to which the conductive structure is attached; the conductive structure includes an undefined conductive layer; and bonding the conductive layer structure to the adhesive pattern layer, which is combined with the core substrate; wherein the base layer and the adhesive pattern layer are located on opposite sides of the conductive layer.

In one embodiment of the manufacturing method of the electronic device, in the step of forming the single-sided structure assembly, after the step of arranging the conductive layer structure: removing (peeling off) the base layer; and patterning the undefined conductive layer, and forming an insulating layer interwoven with the conductive layer.

In one embodiment of the manufacturing method of the electronic device, in the step of forming the single-sided structure assembly, wherein in the step of arranging the conductive layer structure includes the steps of: preparing the conductive layer structure; wherein the conductive layer structure includes a conductive structure and a base layer to which the conductive structure is attached; the conductive structure includes a patterned single or multiple conductive layers, and an insulating layer interwoven with the conductive layer(s); removing at least a part of the base layer; and bonding the conductive layer structure to the adhesive pattern layer, which is combined with the core substrate; wherein the base layer and the adhesive pattern layer are located on opposite sides of the conductive layer.

In one embodiment of the manufacturing method of the electronic device, in the step of forming the single-sided structure assembly, wherein in the step of removing at least a part of the base layer, the base layer includes a first base layer to which the conductive structure is attached, and a second base layer attached to the first base layer, the second base layer and the conductive structure are located on opposite sides of the first base layer; this step further includes: removing the second base layer.

In one embodiment of the manufacturing method of the electronic device, in the step of forming the single-sided structure assembly, wherein in the step of removing at least a part of the base layer, this step further includes: completely removing the base layer.

In one embodiment of the manufacturing method of the electronic device, in the step of forming the single-sided structure assembly, wherein after the step of removing at least a part of the base layer, the manufacturing method further includes the steps of: forming one or more external linking holes in the conductive layer structure, exposing at least a part of the corresponding conductive layer; wherein the external linking hole(s) include an opening formed in the insulating layer.

In one embodiment of the manufacturing method of the electronic device, in the step of forming the single-sided structure assembly, wherein after the step of removing at least a part of the base layer, the manufacturing method further includes the steps of: forming one or more external linking holes in the conductive layer structure, exposing at least a part of the corresponding conductive layer; wherein the external linking hole(s) include an opening formed in the insulating layer, and the external linking hole(s) further include a through hole in the base layer.

In one embodiment of the manufacturing method of the electronic device, the insulating layers include PI, Silicon Nitride, Silicon oxides, Alumina, Aluminum Nitride, Silicon Carbide, Magnesia, Titania, Lead Zirconate Titanate (PZT), epoxy resin materials, or any combination of the aforementioned materials.

In one embodiment of the manufacturing method of the electronic device, the first base layer includes polyimide material.

In one embodiment of the manufacturing method of the electronic device, the second base layer includes at least one of glass, ceramic, and glass-ceramic material.

In one embodiment of the manufacturing method of the electronic device, in the step of forming the single-sided structure assembly, wherein after the step of forming the external linking hole(s), the manufacturing method further includes the steps of: arranging an external conductive structure, placed in the corresponding external linking hole(s), electrically connected to the corresponding conductive layer.

In one embodiment of the manufacturing method of the electronic device, in the step of forming the single-sided structure assembly, wherein in the step of arranging the external conductive structure, the manufacturing method further includes: the steps of performing surface treatment on the exposed portion of the conductive layer corresponding to the external linking hole(s), forming a surface treatment layer.

In one embodiment of the manufacturing method of the electronic device, in the step of forming the single-sided structure assembly, wherein in the step of arranging the external conductive structure, the manufacturing method further includes the steps of: placing an external conductive member on the exposed portion of the conductive layer corresponding to the external linking hole(s).

In one embodiment of the manufacturing method of the electronic device, in the step of forming the single-sided structure assembly, wherein in the step of arranging the external conductive structure the manufacturing method further includes the steps of: placing an external conductive member on the surface treatment layer.

In one embodiment of the manufacturing method of the electronic device, the surface treatment layer includes one or any combination of conductive materials among copper, nickel, gold, silver, chromium, titanium, tungsten, and tin.

In one embodiment of the manufacturing method of the electronic device, in the step of forming the single-sided structure assembly, the adhesive pattern layer includes organic materials.

In one embodiment of the manufacturing method of the electronic device, before the step of connecting the conductive layer structure and the adhesive layer, the manufacturing method further includes the steps of: performing surface treatment on the part of the conductive layer corresponding to the opening window to form a surface treatment layer.

In one embodiment of the manufacturing method of the electronic device, the surface treatment layer includes one or any combination of conductive materials among copper, nickel, gold, silver, chromium, titanium, tungsten, and tin.

In one embodiment of the manufacturing method of the electronic device, in the step of arranging the conductive member, the manufacturing method further includes the steps of: forming the conductive member with a conductive core and a conductive interlayer; the conductive core is located in the through hole, the conductive interlayer electrically connects the conductive core and the conductive layer structure; the conductive interlayer extends along the surface of the core substrate corresponding to the conductive layer structure, and is located in the opening window of the adhesive pattern layer.

In one embodiment of the manufacturing method of the electronic device, the conductive core and the conductive interlayer are of the same material.

In one embodiment of the manufacturing method of the electronic device, in the step of forming the single-sided structure assembly, the conductive layer structure defines an interconnection area corresponding to the opening window; and in the step of arranging the conductive member, the manufacturing method further includes the steps of: the conductive member extends through the interconnection area into the conductive layer structure, electrically connecting to the corresponding conductive layer.

In one embodiment of the manufacturing method of the electronic device, in the step of arranging the conductive member, the manufacturing method further includes the steps of: pressing the conductive member to make at least a part contact the adhesive pattern layer.

In one embodiment of the manufacturing method of the electronic device, in the step of arranging the conductive member, the other end of the conductive member protrudes from the other side of the core substrate.

In one embodiment of the manufacturing method of the electronic device, after the step of arranging the conductive member, the manufacturing method further includes the steps of: performing surface treatment on the other side of the core substrate to form an external conductive layer, electrically connected to the other end of the conductive member.

In one embodiment of the manufacturing method of the electronic device, after the step of arranging the conductive member, the manufacturing method further includes the steps of: performing surface treatment on the other side of the core substrate to form an external conductive layer, at least partially covering and electrically connected to the other end of the conductive member.

In one embodiment of the manufacturing method of the electronic device, the external conductive layer includes one or any combination of conductive materials among copper, silver, nickel, gold, tin, and bismuth.

In one embodiment of the manufacturing method of the electronic device, in the step of forming the single-sided structure assembly, the step of patterning the undefined conductive layer includes at least one of the following processes: exposure etching, Laser Direct Imaging (LDI), and vacuum thermal evaporation process.

In one embodiment of the manufacturing method of the electronic device, in the step of forming the single-sided structure assembly, the step of implementing the through hole includes: laser drilling, or laser modification followed by wet etching.

In one embodiment of the manufacturing method of the electronic device, in the step of forming the single-sided structure assembly, the step of forming the external linking hole(s) includes at least one of the following processes: exposure etching (photoresist imaging), Laser Direct Imaging (LDI), and vacuum thermal evaporation process.

In one embodiment of the manufacturing method of the electronic device, in the step of forming the single-sided structure assembly, the conductive layer structure includes one or any combination of conductive materials among aluminum and copper.

In one embodiment of the manufacturing method of the electronic device, the step of forming the single-sided structure assembly includes: arranging an adhesive structure to the conductive layer structure; wherein the adhesive structure includes an undefined adhesive layer; connecting the adhesive structure to the core substrate; and before or after the step of connecting the adhesive structure and the core substrate, patterning the undefined adhesive layer to form the adhesive pattern layer.

In one embodiment of the manufacturing method of the electronic device, in the step of forming the single-sided structure assembly, wherein in the step of arranging the adhesive structure to the conductive layer structure, the manufacturing method further includes the steps of: preparing the conductive layer structure; wherein the conductive layer structure includes a conductive structure and a base layer attached to the conductive structure; the conductive structure includes an undefined conductive layer; and attaching the conductive layer structure to the adhesive structure layer; wherein the base layer and the adhesive structure are on opposite sides of the conductive layer; and attaching the adhesive pattern layer of the conductive layer structure to the core substrate.

In one embodiment of the manufacturing method of the electronic device, in the step of forming the single-sided structure assembly, wherein after the step of arranging the conductive layer structure, the manufacturing method further includes the steps of: removing (peeling off) the base layer; and patterning the undefined conductive layer, and form an insulating layer interwoven with the conductive layer.

In one embodiment of the manufacturing method of the electronic device, in the step of forming the single-sided structure assembly, wherein in the step of arranging the adhesive structure to the conductive layer structure the manufacturing method further includes the steps of: preparing the conductive layer structure; wherein the conductive layer structure includes a conductive structure and a base layer attached to the conductive structure; the conductive structure includes patterned single or multiple conductive layers, and an insulating layer interwoven with the conductive layer(s); removing at least a part of the base layer; and attaching the adhesive pattern layer of the conductive layer structure to the core substrate; wherein the base layer and the adhesive pattern layer are on opposite sides of the conductive layer.

In one embodiment of the manufacturing method of the electronic device, in the step of forming the single-sided structure assembly, wherein in the step of removing at least a part of the base layer, the base layer includes a first base layer attached to the conductive structure, and a second base layer attached to the first base layer, with the second base layer and the conductive structure on opposite sides of the first base layer; this step further includes: removing the second base layer.

In one embodiment of the manufacturing method of the electronic device, in the step of forming the single-sided structure assembly, wherein in the step of removing at least a part of the base layer, this step further includes: completely removing the base layer.

In one embodiment of the manufacturing method of the electronic device, in the step of forming the single-sided structure assembly, after the step of removing at least a part of the base layer, further includes: creating one or more external linking holes in the conductive layer structure, exposing at least a part of the corresponding conductive layer; wherein the external linking hole(s) include a through via formed in the insulating layer.

In one embodiment of the manufacturing method of the electronic device, in the step of forming the single-sided structure assembly, wherein after the step of removing at least a part of the base layer, the manufacturing method further includes the steps of: creating one or more external linking holes in the conductive layer structure, exposing at least a part of the corresponding conductive layer; wherein the external linking hole(s) include a through via formed in the insulating layer, and the external linking hole further includes a via in the base layer.

In one embodiment of the manufacturing method of the electronic device, the insulating layers include PI, Silicon Nitride, Silicon oxides, Alumina, Aluminum Nitride, Silicon Carbide, Magnesia, Titania, Lead Zirconate Titanate (PZT), epoxy resin materials, or any combination of the aforementioned materials.

In one embodiment of the manufacturing method of the electronic device, the first base layer includes polyimide material.

In one embodiment of the manufacturing method of the electronic device, the second base layer includes at least one of glass, ceramic, and glass-ceramic material.

In one embodiment of the manufacturing method of the electronic device, in the step of forming the single-sided structure assembly, wherein after the step of creating the external linking hole(s), the manufacturing method further includes the steps of: arranging an external conductive structure, placed in the corresponding external linking hole(s), electrically connected to the corresponding conductive layer.

In one embodiment of the manufacturing method of the electronic device, in the step of forming the single-sided structure assembly, wherein in the step of arranging the external conductive structure, the manufacturing method further includes the steps of: performing surface treatment on the exposed portion of the corresponding conductive layer in the external linking hole(s), forming a surface treatment layer.

In one embodiment of the manufacturing method of the electronic device, in the step of forming the single-sided structure assembly, wherein in the step of arranging the external conductive structure, the manufacturing method further includes the steps of: placing an external conductive member on the exposed portion of the corresponding conductive layer in the external linking hole(s).

In one embodiment of the manufacturing method of the electronic device, in the step of forming the single-sided structure assembly, wherein in the step of arranging the external conductive structure, the manufacturing method further includes the steps of: placing an external conductive member on the surface treatment layer.

In one embodiment of the manufacturing method of the electronic device, the surface treatment layer includes one or any combination of conductive materials from copper, nickel, gold, silver, chromium, titanium, tungsten, and tin.

In one embodiment of the manufacturing method of the electronic device, before the step of connecting the conductive layer structure and the adhesive layer, the manufacturing method further includes the steps of: performing surface treatment on the part of the conductive layer corresponding to the opening window, forming a surface treatment layer.

In one embodiment of the manufacturing method of the electronic device, the surface treatment layer includes one or any combination of conductive materials from copper, nickel, gold, silver, chromium, titanium, tungsten, and tin.

In one embodiment of the manufacturing method of the electronic device, in the step of arranging the conductive member, the other end of the conductive member protrudes from the other side of the core substrate.

In one embodiment of the manufacturing method of the electronic device, after the step of arranging the conductive member, the manufacturing method further includes the steps of: performing surface treatment on the other side of the core substrate, forming an external conductive layer, electrically connected to the other end of the conductive member.

In one embodiment of the manufacturing method of the electronic device, after the step of arranging the conductive member, the manufacturing method further includes the steps of: performing surface treatment on the other side of the core substrate, forming an external conductive layer, at least partially covering and electrically connected to the other end of the conductive member.

In one embodiment of the manufacturing method of the electronic device, the external conductive layer includes one or any combination of conductive materials from copper, silver, nickel, gold, tin, and bismuth.

In one embodiment of the manufacturing method of the electronic device, the external conductive layer includes one or any combination of conductive materials from copper, silver, nickel, gold, tin, and bismuth.

In one embodiment of the manufacturing method of the electronic device, in the step of forming the single-sided structure assembly, wherein the step of patterning the undefined conductive layer includes at least one process from: exposure etching, Laser Direct Imaging (LDI), and vacuum thermal evaporation process.

In one embodiment of the manufacturing method of the electronic device, in the step of forming the single-sided structure assembly, wherein the step of forming the external linking hole(s) includes at least one process from: exposure etching (photoresist imaging), Laser Direct Imaging (LDI), and vacuum thermal evaporation process.

In one embodiment of the manufacturing method of the electronic device, in the step of forming the single-sided structure assembly, the conductive layer structure includes one or any combination of conductive materials from aluminum and copper.

In one embodiment of the manufacturing method of the electronic device, the step of forming the single-sided structure assembly further includes the steps of: preparing the core substrate; and laminating the conductive layer structure to one side of the core substrate, forming the adhesive pattern layer between the core substrate or the conductive layer structure; wherein the adhesive pattern layer includes metal compounds or metal transitional materials.

In one embodiment of the manufacturing method of the electronic device, the step of forming the single-sided structure assembly further includes the steps of: in the step of laminating the conductive layer structure: the conductive layer structure includes an undefined conductive layer; and face-to-face laminating the conductive layer structure to the core substrate.

In one embodiment of the manufacturing method of the electronic device, in the step of forming the single-sided structure assembly, the conductive layer structure includes a conductive structure and a base layer connected to the conductive structure; the conductive structure includes the undefined conductive layer: after the step of laminating the conductive layer structure: removing (peeling off) the base layer; and patterning the undefined conductive layer, and forming an insulating layer interwoven with the conductive layer.

In one embodiment of the manufacturing method of the electronic device, in the step of forming the single-sided structure assembly, wherein after the step of removing at least part of the base layer, the manufacturing method further includes the steps of: creating one or more external linking holes in the conductive layer structure, exposing a corresponding part of the conductive layer; wherein the external linking hole(s) include an opening formed in the insulating layer.

In one embodiment of the manufacturing method of the electronic device, the insulating layers include PI, Silicon Nitride, Silicon oxides, Alumina, Aluminum Nitride, Silicon Carbide, Magnesia, Titania, Lead Zirconate Titanate (PZT), epoxy resin materials, or any combination of the aforementioned materials.

In one embodiment of the manufacturing method of the electronic device, in the step of forming the single-sided structure assembly, wherein after the step of creating the external linking hole(s), the manufacturing method further includes the steps of: arranging an external conductive structure, placed at the corresponding external linking hole(s), electrically connected to the corresponding conductive layer.

In one embodiment of the manufacturing method of the electronic device, in the step of forming the single-sided structure assembly, wherein in the step of arranging the external conductive structure, the manufacturing method further includes the steps of: performing surface treatment on the exposed part of the conductive layer corresponding to the external linking hole(s), forming a surface treatment layer.

In one embodiment of the manufacturing method of the electronic device, in the step of forming the single-sided structure assembly, wherein in the step of arranging the external conductive structure, the manufacturing method further includes the steps of: placing an external conductive member on the exposed part of the conductive layer corresponding to the external linking hole(s).

In one embodiment of the manufacturing method of the electronic device, in the step of forming the single-sided structure assembly, wherein in the step of arranging the external conductive structure, the manufacturing method further includes the steps of: placing an external conductive member on the surface treatment layer.

In one embodiment of the manufacturing method of the electronic device, the surface treatment layer includes one or any combination of conductive materials from copper, nickel, gold, silver, chromium, titanium, tungsten, and tin.

In one embodiment of the manufacturing method of the electronic device, before the step of connecting the conductive layer structure and the adhesive layer, the manufacturing method further includes the steps of: performing surface treatment on the part of the conductive layer corresponding to the opening window, forming a surface treatment layer.

In one embodiment of the manufacturing method of the electronic device, the surface treatment layer includes one or any combination of conductive materials from copper, nickel, gold, silver, chromium, titanium, tungsten, and tin.

In one embodiment of the manufacturing method of the electronic device, in the step of arranging the conductive member, the other end of the conductive member protrudes from the other side of the core substrate.

In one embodiment of the manufacturing method of the electronic device, after the step of arranging the conductive member, the manufacturing method further includes the steps of: performing surface treatment on the other side of the core substrate, forming an external conductive layer, electrically connected to the other end of the conductive member.

In one embodiment of the manufacturing method of the electronic device, after the step of arranging the conductive member, the manufacturing method further includes the steps of: performing surface treatment on the other side of the core substrate, forming an external conductive layer, at least partially covering and electrically connected to the other end of the conductive member.

In one embodiment of the manufacturing method of the electronic device, the external conductive layer includes one or any combination of conductive materials from copper, silver, nickel, gold, tin, and bismuth.

In one embodiment of the manufacturing method of the electronic device, in the step of forming the single-sided structure assembly, wherein the step of patterning the undefined conductive layer includes at least one process from: exposure etching, Laser Direct Imaging (LDI), and vacuum thermal evaporation process.

In one embodiment of the manufacturing method of the electronic device, in the step of forming the single-sided structure assembly, wherein the step of forming the external linking hole(s) includes at least one process from: exposure etching (photoresist imaging), Laser Direct Imaging (LDI), and vacuum thermal evaporation process.

In one embodiment of the manufacturing method of the electronic device, after the step of arranging the conductive component, the manufacturing method further includes the steps of: arranging an associate adhesive pattern layer on the other side of the core substrate, the associate adhesive pattern layer having an opening window; wherein the through hole and the opening window overlap at least partially in the projection direction; and arranging an associate conductive layer structure, connected to the associate adhesive pattern layer, and located on the opposite side of the associate adhesive pattern layer from the core substrate; wherein the opening window of the associate adhesive pattern layer exposes at least a part of the associate conductive layer structure, the associate conductive layer structure covers at least a part of the through hole, and the conductive component electrically connects to the associate conductive layer structure through the opening window of the associate adhesive pattern layer.

In one embodiment of the manufacturing method of the electronic device, the associate conductive layer structure and the through hole overlap at least partially in the projection direction.

One or more exemplary embodiments of this disclosure are to provide a manufacturing method of an electronic device. The manufacturing method includes steps below:
forming a single-sided structure assembly; wherein the single-sided structure assembly includes: a core substrate, having a through hole penetrating its two surfaces; defining a projection direction perpendicular to one surface of the core substrate; a conductive layer structure, stacked over one side of the core substrate, and the conductive layer structure covers at least a part of the through hole; an adhesive pattern layer, located between the conductive layer structure and the core substrate, and bonding the conductive layer structure and the core substrate; the adhesive pattern layer having an opening window that exposes at least a part of the conductive layer structure; wherein the through hole and the opening window overlap at least partially in the projection direction;
arranging a conductive material in the through hole of the core substrate;
arranging an associate structure on the other side of the core substrate; wherein the associate structure includes an associate adhesive pattern layer and the associate conductive layer structure, the associate conductive layer structure is connected to the associate adhesive pattern layer and is located on the opposite side of the associate adhesive pattern layer from the core substrate; the associate adhesive pattern layer has an opening window, the opening window of the associate adhesive pattern layer exposes at least a part of the associate conductive layer structure, and the associate conductive layer structure covers at least a part of the through hole; and
thermally curing the conductive material to form the conductive component; wherein one end of the conductive component electrically connects to the conductive layer structure through the opening window of the adhesive pattern layer, and the other end of the conductive component electrically connects to the associate conductive layer structure through the opening window of the associate adhesive pattern layer.

In one embodiment of the manufacturing method of the electronic device, before or during the step of thermally curing the conductive component, the manufacturing method further includes the steps of: forming the conductive component with a conductive core and a conductive interface layer; the conductive core is located in the through hole, the conductive interface layer electrically connects the conductive core to the conductive layer structure or the associate conductive layer structure; the conductive interface layer extends along the surface of the core substrate corresponding to the conductive layer structure and is located in the opening window of the adhesive pattern layer, or the conductive interface layer extends along the surface of the core substrate corresponding to the associate conductive layer structure and is located in the opening window of the associate adhesive pattern layer.

In one embodiment of the manufacturing method of the electronic device, before the step of thermally curing the conductive component, the conductive layer structure and the associate conductive layer structure include a conductive structure and a base layer connected to the conductive structure; the conductive structure includes an undefined conductive layer.

In one embodiment of the manufacturing method of the electronic device, after the step of thermally curing the conductive component, the manufacturing method further includes the steps of: peeling off the base layer; and patterning the undefined conductive layer, and forming an insulating layer interwoven with the conductive layer; and creating one or more external linking holes on the conductive layer structure and the associate conductive layer structure, some of these external linking holes expose a portion of the corresponding conductive layer, some of these external linking holes expose a portion of the corresponding associate conductive layer; wherein the external linking hole(s) include an opening formed in the insulating layer.

In one embodiment of the manufacturing method of the electronic device, before the step of thermally curing the conductive component, the conductive layer structure and the associate conductive layer structure include a conductive structure and a base layer connected to the conductive structure; the conductive structure includes a patterned single or multiple conductive layers, and an insulating layer interwoven with the conductive layer(s); and after the step of thermally curing the conductive component, further comprising: creating one or more external linking holes on the conductive layer structure and the associate conductive layer structure, some of these external linking holes expose a portion of the corresponding conductive layer, some of these external linking holes expose a portion of the corresponding associate conductive layer; wherein the external linking hole(s) include an opening formed in the insulating layer.

In one embodiment of the manufacturing method of the electronic device, the insulating layers include PI, Silicon Nitride, Silicon oxides, Alumina, Aluminum Nitride, Silicon Carbide, Magnesia, Titania, Lead Zirconate Titanate (PZT), epoxy resin materials, or any combination of the aforementioned materials.

In one embodiment of the manufacturing method of the electronic device, in the step of forming the single-sided structure assembly, wherein after the step of creating the external linking hole(s), the manufacturing method further includes the steps of: arranging an external conductive structure, placed in the corresponding external linking hole, electrically connected to the corresponding conductive layer.

In one embodiment of the manufacturing method of the electronic device, in the step of forming the single-sided structure assembly, wherein in the step of arranging the external conductive structure, the manufacturing method further includes the steps of: performing surface treatment on the part of the conductive layer exposed by the external linking hole(s) to form a surface treatment layer.

In one embodiment of the manufacturing method of the electronic device, in the step of forming the single-sided structure assembly, wherein in the step of arranging the external conductive structure, the manufacturing method further includes the steps of: placing an external conductive member on the part of the conductive layer exposed by the external linking hole(s).

In one embodiment of the manufacturing method of the electronic device, in the step of forming the single-sided structure assembly, wherein in the step of arranging the external conductive structure, the manufacturing method further includes the steps of: placing an external conductive member on the surface treatment layer.

In one embodiment of the manufacturing method of the electronic device, the surface treatment layer includes one or any combination of conductive materials from copper, nickel, gold, silver, chromium, titanium, tungsten, and tin.

In one embodiment of the manufacturing method of the electronic device, in the step of forming the single-sided structure assembly, the adhesive pattern layer includes organic materials.

In one embodiment of the manufacturing method of the electronic device, before the step of connecting the conductive layer structure and the adhesive layer, the manufacturing method further includes the steps of: performing surface treatment on the part of the conductive layer corresponding to the opening window to form a surface treatment layer.

In one embodiment of the manufacturing method of the electronic device, the surface treatment layer includes one or any combination of conductive materials from copper, nickel, gold, silver, chromium, titanium, tungsten, and tin.

In one embodiment of the manufacturing method of the electronic device, the conductive layer structure defines an interconnection area corresponding to the opening window; the manufacturing method further includes the steps of: in the step of thermally curing the conductive material, further comprising: forming the conductive component to extend through the interconnection area into the conductive layer structure, or/and the associate conductive layer structure, and electrically connect to the corresponding conductive layer.

In one embodiment of the manufacturing method of the electronic device, in the step of thermally curing the conductive material, the manufacturing method further includes the steps of: approaching the conductive component to make at least a part contact the adhesive pattern layer, or/and the associate adhesive pattern layer.

In one embodiment of the manufacturing method of the electronic device, the step of patterning the undefined conductive layer includes at least one process from: exposure etching, Laser Direct Imaging (LDI), and vacuum thermal evaporation process.

In one embodiment of the manufacturing method of the electronic device, the step of forming the external linking hole(s) includes at least one process from: exposure etching (photoresist imaging), Laser Direct Imaging (LDI), and vacuum thermal evaporation process.

In one embodiment of the manufacturing method of the electronic device, the conductive layer structure includes one of aluminum or copper, or any combination of conductive materials.

One or more exemplary embodiments of this disclosure are to provide a manufacturing method of an electronic device. The manufacturing method includes steps below:
providing an undefined initial substrate;
stacking an adhesive structure and an associate adhesive structure on opposite sides of the initial substrate; wherein the adhesive structure and the associate adhesive structure each include an undefined adhesive layer and a release layer; wherein the adhesive layer is between the release layer and the initial substrate;
performing a through hole process on the initial substrate and its bonded adhesive structure and associate adhesive structure; wherein the initial substrate defines a through hole forming a core substrate; the adhesive structure and the associate adhesive structure each define an opening window to form an adhesive pattern layer and an associate adhesive pattern layer respectively;
removing the release layer of the adhesive structure;
attaching a conductive layer structure to the adhesive pattern layer, the conductive layer structure covering at least a part of the corresponding through hole;
arranging a conductive material in the through hole;
removing the release layer of the associate adhesive structure;
arranging an associate conductive layer structure on the associate adhesive pattern layer; and
thermally curing the conductive material to form a conductive component; the conductive component passes through the corresponding opening areas and is electrically connected at both ends to the conductive layer structure and the associate conductive layer structure.

In one embodiment of the manufacturing method of the electronic device, the conductive component includes one of copper, silver, tin, and bismuth, or any combination of conductive materials.

In one embodiment of the manufacturing method of the electronic device, the conductive component includes one or more conductive materials, where the volume of these conductive materials is not less than 70% of the volume of the through hole.

In one embodiment of the manufacturing method of the electronic device, the conductive component contains resin material.

In one embodiment of the manufacturing method of the electronic device, there are multiple through holes and conductive components, with each conductive component corresponding to one of the through holes.

In one embodiment of the manufacturing method of the electronic device, the conductive component extends into the conductive layer structure.

In one embodiment of the manufacturing method of the electronic device, the core substrate is made of inorganic material.

In one embodiment of the manufacturing method of the electronic device, the core substrate includes at least one of glass, ceramic, and glass-ceramic material.

In one embodiment of the manufacturing method of the electronic device, the thermal expansion coefficient of the core substrate is not greater than 30 ppm/° C. and not less than 17 ppm/° C.

In one embodiment of the manufacturing method of the electronic device, the core substrate is a single substrate.

In one embodiment of the manufacturing method of the electronic device, in the step of arranging the conductive layer structure, the manufacturing method further includes the steps of: preparing the conductive layer structure; wherein the conductive layer structure includes a conductive structure and a substrate attached to the conductive structure; the conductive structure includes an undefined conductive layer; and attaching the conductive layer structure to the adhesive pattern layer combined with the core substrate; wherein the base layer and the adhesive pattern layer are on opposite sides of the conductive layer.

In one embodiment of the manufacturing method of the electronic device, in the step of arranging the associate conductive layer structure, the manufacturing method further includes the steps of: preparing the associate conductive layer structure; wherein the conductive layer structure includes a conductive structure and a substrate attached to the conductive structure; the conductive structure includes an undefined conductive layer; and attaching the associate conductive layer structure to the adhesive pattern layer combined with the core substrate; wherein the base layer and the adhesive pattern layer are on opposite sides of the conductive layer.

In one embodiment of the manufacturing method of the electronic device, after the step of thermally curing the conductive material, the manufacturing method further includes the steps of: peeling off the base layer of the conductive layer structure and the associate conductive layer structure; and patterning the undefined conductive layer, and forming an insulating layer interwoven with the conductive layer.

In one embodiment of the manufacturing method of the electronic device, after the step of patterning the conductive layer, the manufacturing method further includes the steps of: creating one or more external linking holes in the conductive layer structure, exposing at least a part of the corresponding conductive layer; wherein the external linking hole(s) include an opening formed in the insulating layer.

In one embodiment of the manufacturing method of the electronic device, the insulating layers include PI, Silicon Nitride, Silicon oxides, Alumina, Aluminum Nitride, Silicon Carbide, Magnesia, Titania, Lead Zirconate Titanate (PZT), epoxy resin material, or any combination of the aforementioned materials.

In one embodiment of the manufacturing method of the electronic device, after the step of creating the external linking hole(s), the manufacturing method further includes the steps of: arranging an external conductive structure, placed in the corresponding external linking hole(s), electrically connected to the corresponding conductive layer.

In one embodiment of the manufacturing method of the electronic device, in the step of arranging the external conductive structure, the manufacturing method further includes the steps of: performing surface treatment on the exposed portion of the conductive layer corresponding to the external linking hole(s), forming a surface treatment layer.

In one embodiment of the manufacturing method of the electronic device, in the step of arranging the external conductive structure, the manufacturing method further includes the steps of: placing an external conductive member on the exposed portion of the conductive layer corresponding to the external linking hole(s).

In one embodiment of the manufacturing method of the electronic device, in the step of arranging the external conductive structure, the manufacturing method further includes the steps of: placing an external conductive member on the surface treatment layer.

In one embodiment of the manufacturing method of the electronic device, the surface treatment layer includes one of copper, nickel, gold, silver, chromium, titanium, tungsten, tin or any combination of conductive materials.

In one embodiment of the manufacturing method of the electronic device, the adhesive pattern layer and the associate adhesive pattern layer include organic materials.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 and FIG. 1′ are cross-sectional schematic views, along projection direction D1, of different embodiments of a single-sided structure of the disclosed electronic device.

FIG. 1M and FIG. 1M′ are cross-sectional schematic views, along projection direction D1, of another embodiment of the single-sided structure in which the conductive component further includes a conductive interface layer.

FIG. 1X and FIG. 1X′ are cross-sectional schematic views corresponding to FIG. 1 and FIG. 1′, further including an external conductive layer.

FIG. 1Y is cross-sectional schematic view of FIG. 1X showing a layered external conductive layer.

FIG. 2A is cross-sectional schematic view of an embodiment of FIG. 1 having a layered conductive layer structure and an external conductive structure.

FIG. 2AN is cross-sectional schematic view of FIG. 2A further having a layered external conductive layer.

FIG. 2AN1 is cross-sectional schematic view of FIG. 2AN in which the conductive layer structure further includes a base layer.

FIG. 2AX is cross-sectional schematic view of FIG. 2A further having an external conductive layer.

FIG. 2AX1 is cross-sectional schematic view of FIG. 2AX in which the conductive layer structure further includes a base layer.

FIG. 2AY is cross-sectional schematic view of FIG. 2A further having a layered external conductive layer.

FIG. 2AY1 is cross-sectional schematic view of FIG. 2AY in which the conductive layer structure further includes a base layer.

FIG. 2B is cross-sectional schematic view of another embodiment in which the conductive layer structure of FIG. 1 is layered together with its external conductive structure.

FIG. 2BN is cross-sectional schematic view of FIG. 2B further having a layered external conductive layer.

FIG. 2BN′ is cross-sectional schematic view of FIG. 2BN in which the conductive component further has a surface treatment layer.

FIG. 2BN1 is cross-sectional schematic view of FIG. 2BN in which the conductive layer structure further includes a base layer.

FIG. 2BN1′ is cross-sectional schematic view of FIG. 2BN′ in which the conductive layer structure further includes a base layer.

FIG. 2BX is cross-sectional schematic view of FIG. 2B further having an external conductive layer.

FIG. 2BX′ is cross-sectional schematic view of FIG. 2BX in which the conductive component further has a surface treatment layer.

FIG. 2BX1 is cross-sectional schematic view of FIG. 2BX in which the conductive layer structure further includes a base layer.

FIG. 2BX1′ is cross-sectional schematic view of FIG. 2BX′ in which the conductive layer structure further includes a base layer.

FIG. 2BY is cross-sectional schematic view of FIG. 2B further having a layered external conductive layer.

FIG. 2BY′ is cross-sectional schematic view of FIG. 2BY in which the conductive component further has a surface treatment layer.

FIG. 2BY1 is cross-sectional schematic view of FIG. 2BY in which the conductive layer structure further includes a base layer.

FIG. 2BY1′ is cross-sectional schematic view of FIG. 2BY′ in which the conductive layer structure further includes a base layer.

FIG. 2C is cross-sectional schematic view of yet another embodiment of FIG. 1 having a layered conductive layer structure and an external conductive structure.

FIG. 2CN is cross-sectional schematic view of FIG. 2C further having a layered external conductive layer.

FIG. 2CN′ is cross-sectional schematic view of FIG. 2C in which the conductive component further has a surface treatment layer.

FIG. 2CN1 is cross-sectional schematic view of FIG. 2CN in which the conductive layer structure further includes a base layer.

FIG. 2CN1′ is cross-sectional schematic view of FIG. 2CN′ in which the conductive layer structure further includes a base layer.

FIG. 2CX is cross-sectional schematic view of FIG. 2C further having an external conductive layer.

FIG. 2CX′ is cross-sectional schematic view of FIG. 2CX in which the conductive component further has a surface treatment layer.

FIG. 2CX1 is cross-sectional schematic view of FIG. 2CX in which the conductive layer structure further includes a base layer.

FIG. 2CX1′ is cross-sectional schematic view of FIG. 2CX′ in which the conductive layer structure further includes a base layer.

FIG. 2CY is cross-sectional schematic view of FIG. 2C further having a layered external conductive layer.

FIG. 2CY′ is cross-sectional schematic view of FIG. 2CY in which the conductive component further has a surface treatment layer.

FIG. 2CY1 is cross-sectional schematic view of FIG. 2CY in which the conductive layer structure further includes a base layer.

FIG. 2CY1′ is cross-sectional schematic view of FIG. 2CY′ in which the conductive layer structure further includes a base layer.

FIG. 3 and FIG. 3′ are cross-sectional schematic views corresponding to FIG. 1 and FIG. 1′, showing another embodiment with laminated layers.

FIGS. 4, 4′, 4X, 4X′, and 4Y are cross-sectional schematic views, along projection direction D1, of different embodiments of a double-sided structure of the disclosed electronic device.

FIG. 5AX, 5AZ, 5BX, 5BZ, 5BX′, 5BY, 5CX, 5CX′, 5CZ, and 5CZ′ are cross-sectional schematic views, along projection direction D1, of different embodiments of another double-sided structure of the disclosed electronic device.

FIGS. 6A and 6A′ are cross-sectional schematic views showing different embodiments after completing a single-side process in different processes for the double-sided structure of the disclosed electronic device.

FIGS. 6B and 6B′ are cross-sectional schematic views corresponding to FIGS. 6A and 6A′, showing different embodiments of arranging conductive components.

FIGS. 6C and 6C′ are cross-sectional schematic views corresponding to FIGS. 6B and 6B′, showing different embodiments after completing the process on the other side.

FIG. 7A is cross-sectional schematic view of another embodiment after completing a single-side process in different processes for the double-sided structure.

FIG. 7B is cross-sectional schematic view of arranging conductive components in FIG. 7A.

FIG. 7C is cross-sectional schematic view after completing the process on the other side in FIG. 7B.

FIGS. 8A to 8N, and FIG. 8I′ and 8J′ are cross-sectional schematic views, by process flow, of another process for the double-sided structure of the disclosed electronic device.

FIGS. 9A to 9F are cross-sectional schematic views, by process flow, of yet another process for the double-sided structure of the disclosed electronic device.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

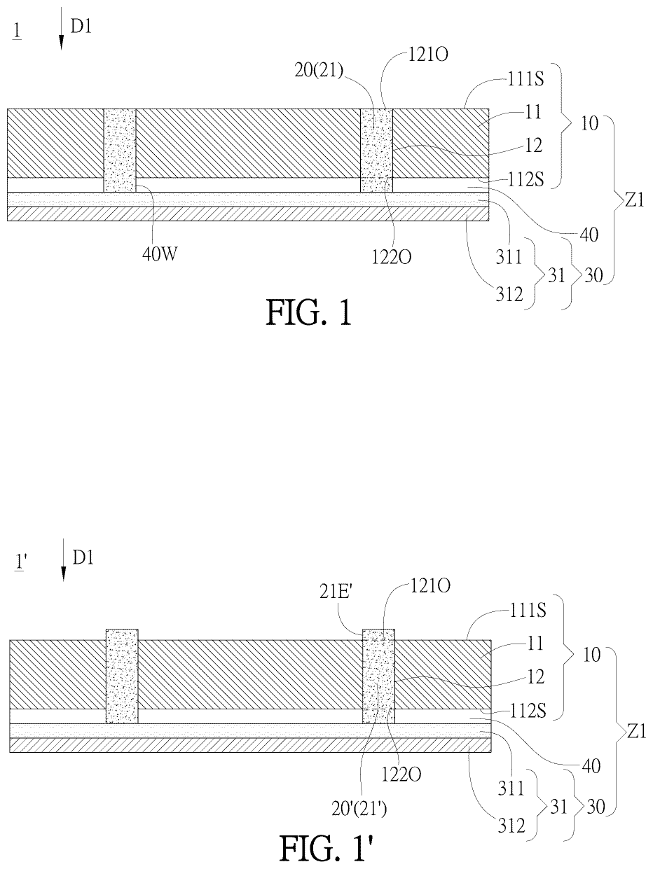

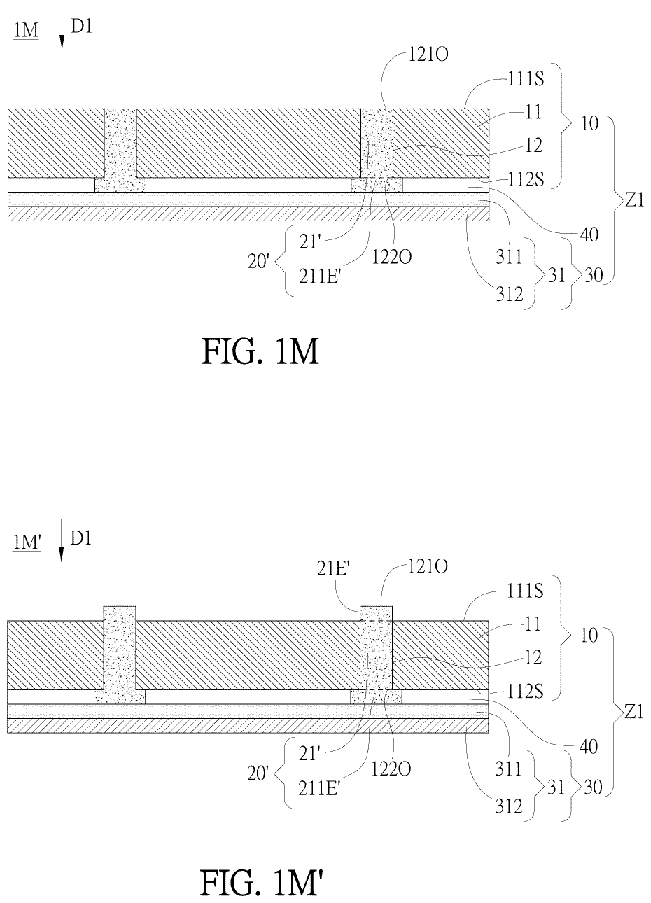

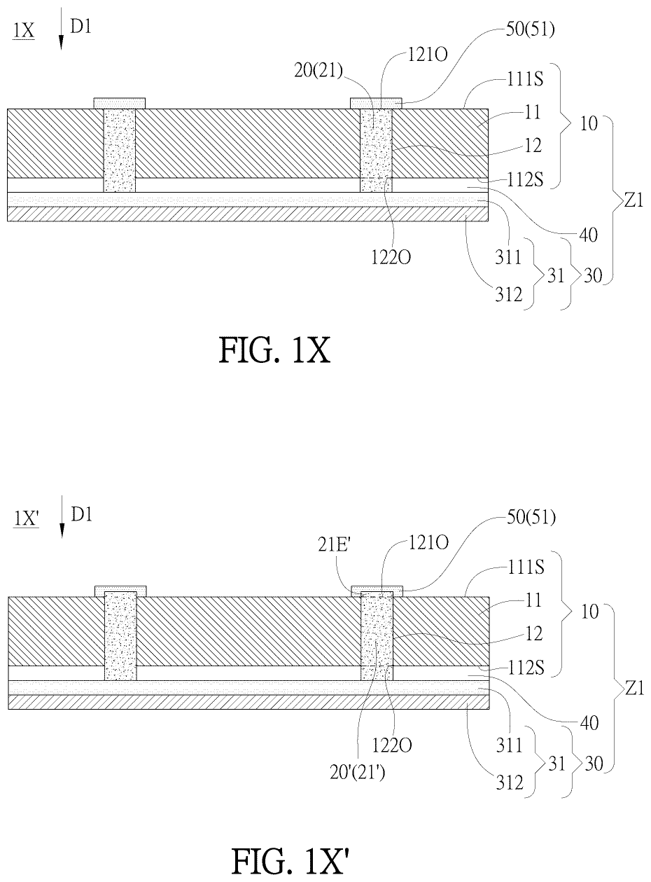

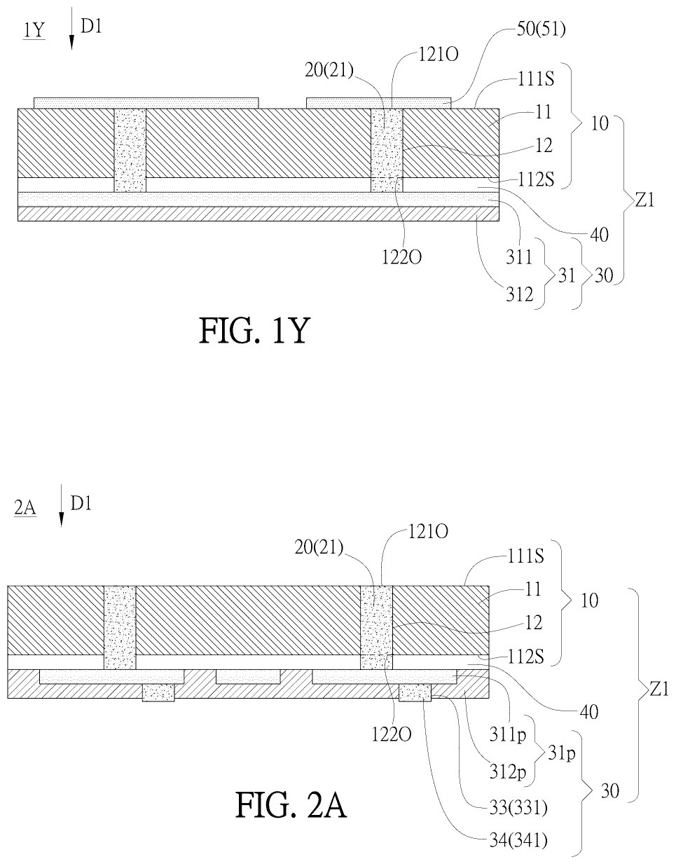

This disclosure provides a method for manufacturing the electronic device 1 referred in FIG. 1 and FIG. 1′, which at least includes the following steps: To provide a core substrate 10 with a through hole 12. To provide an adhesive structure 40 on the core substrate 10 or the conductive layer structure 30. Next step: First, set a conductive pattern layer structure on one side of the core substrate 10 to at least partially cover one end of the through hole 12. Next step: Set a conductive material in the through hole 12, which can contact the conductive layer structure 30 through an opening window 40W of the adhesive structure 40. Next step: Thermally cure the conductive material to form a conductive member 20, with one end of the conductive member 20 electrically connected to the conductive layer structure on one side of the core substrate 10, while the other end is exposed. At this embodiment of the method, a simple single-sided structure Z1 can be completed.

As another embodiment of the method, steps may be adding or various after or mixed within the previous steps. Such as:

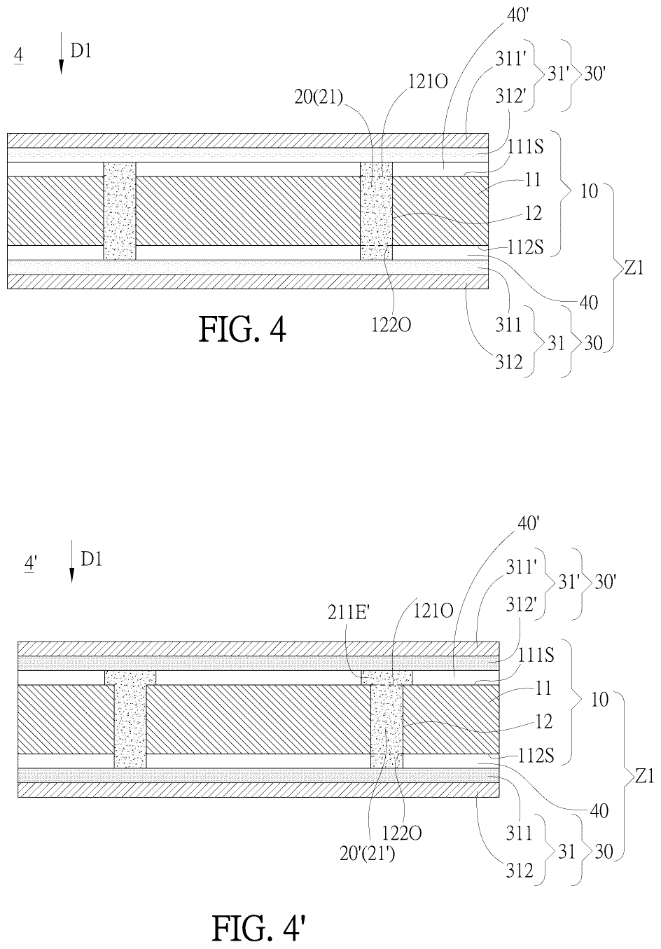

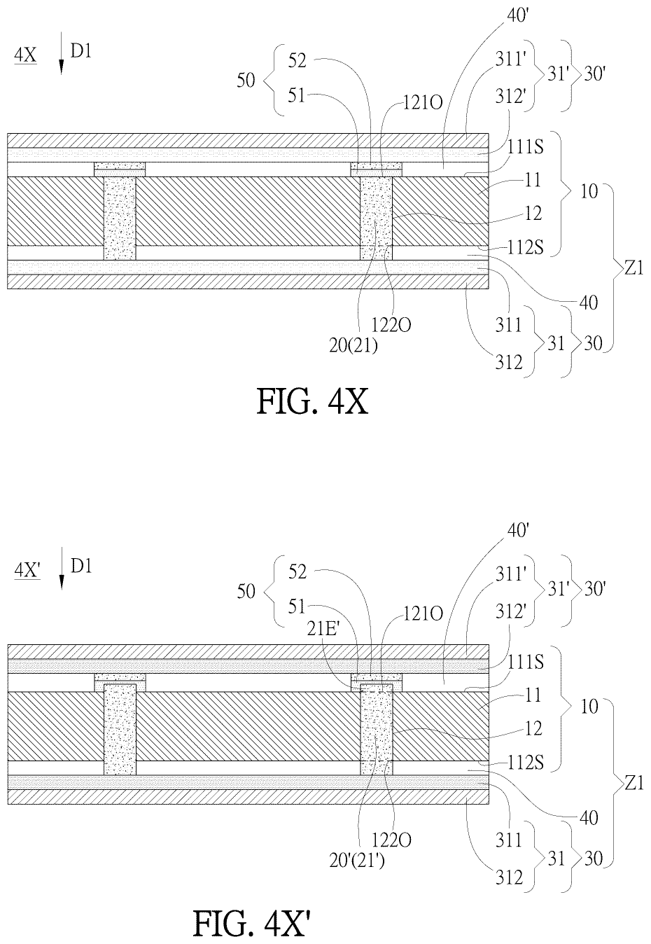

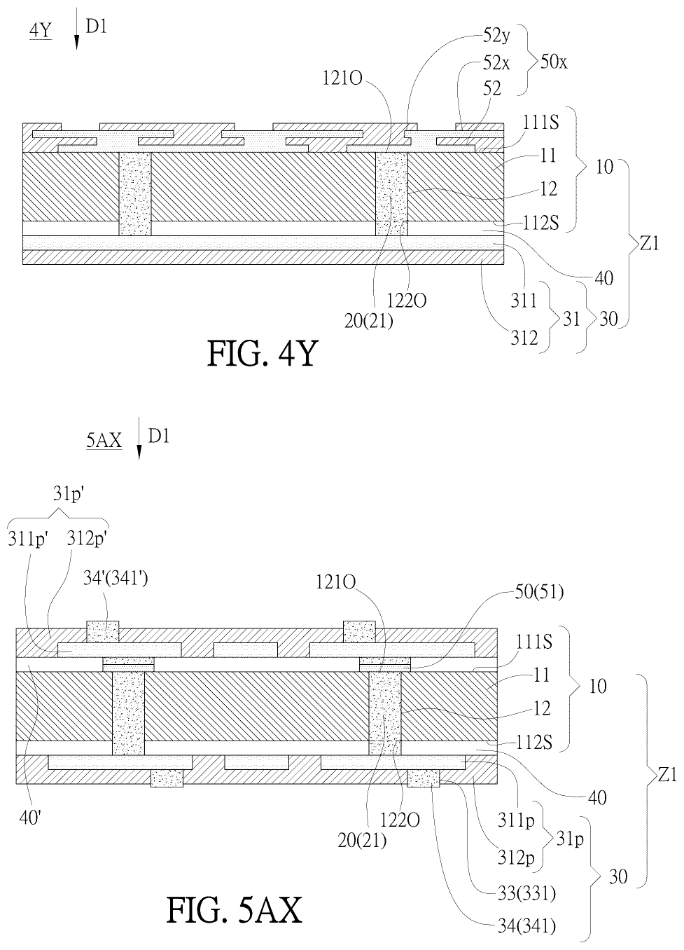

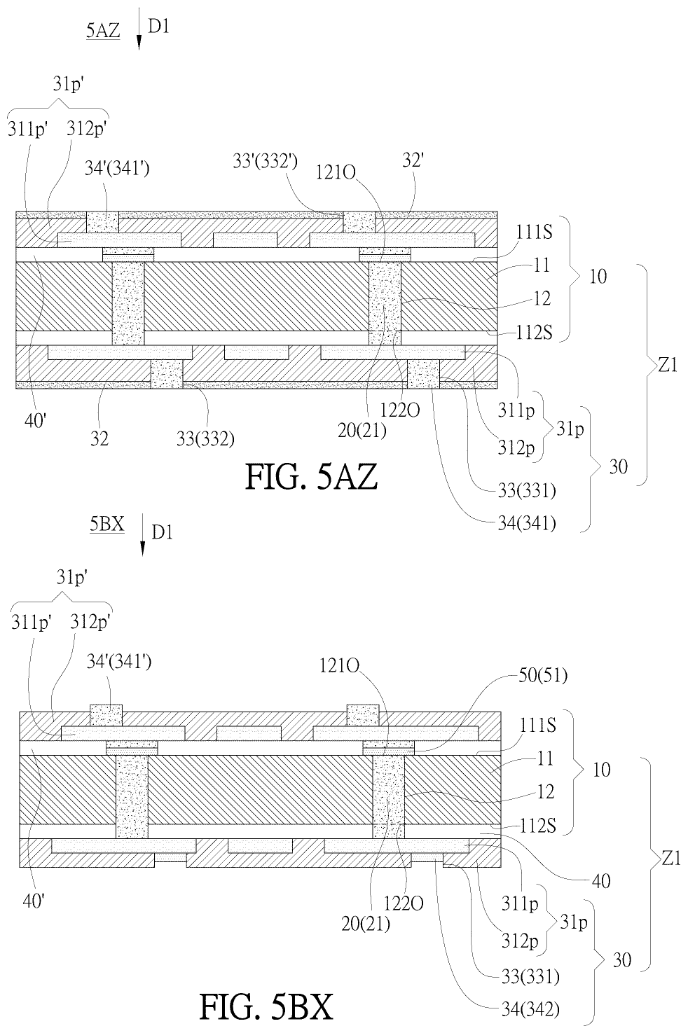

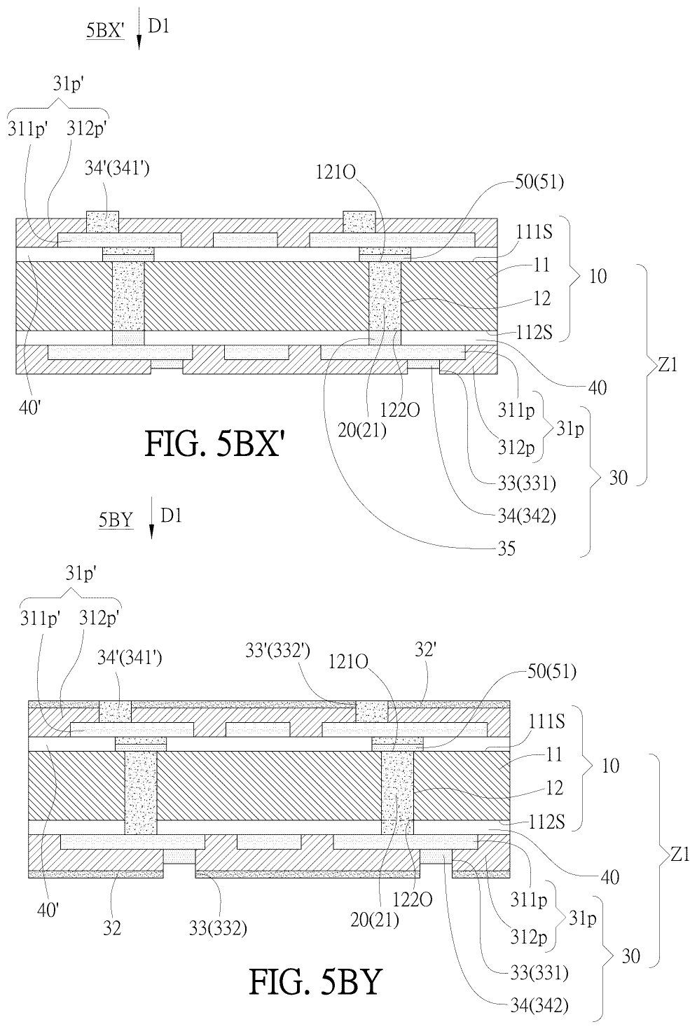

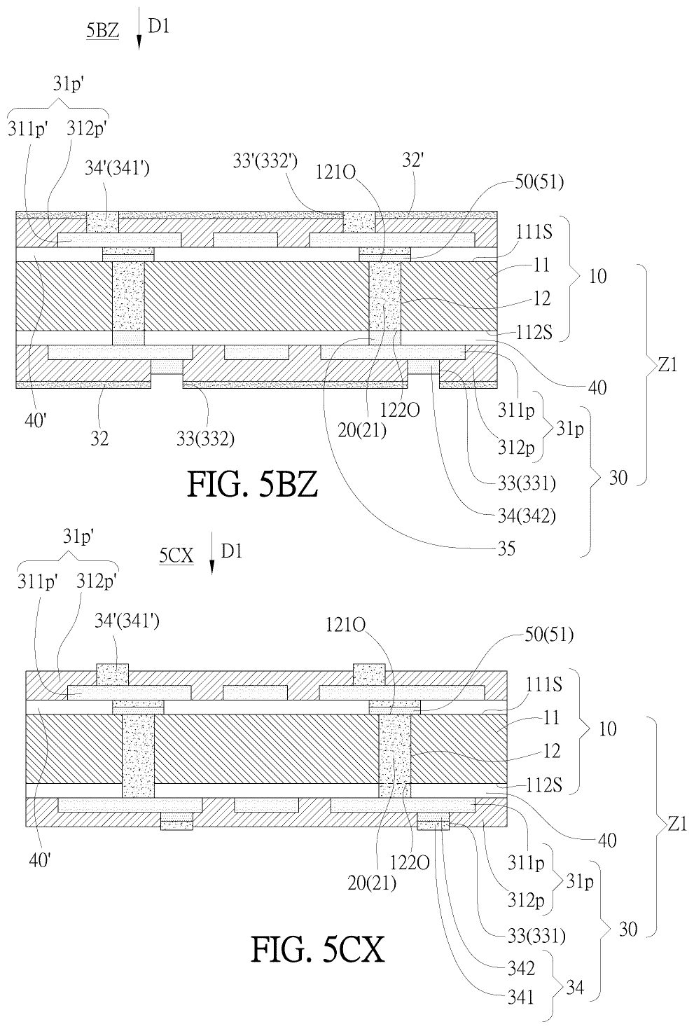

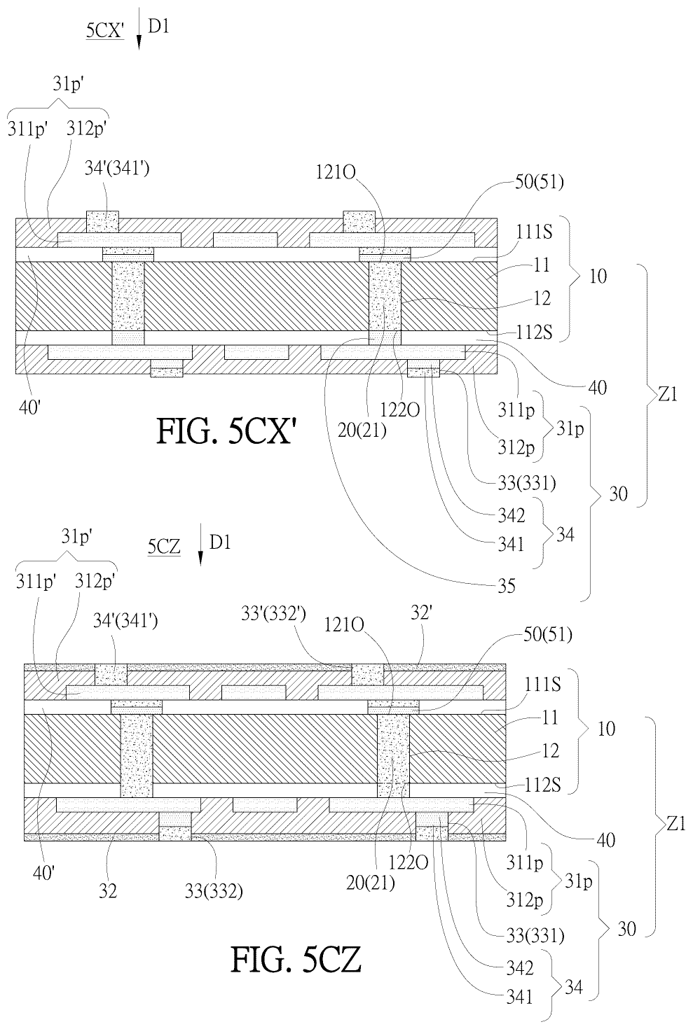

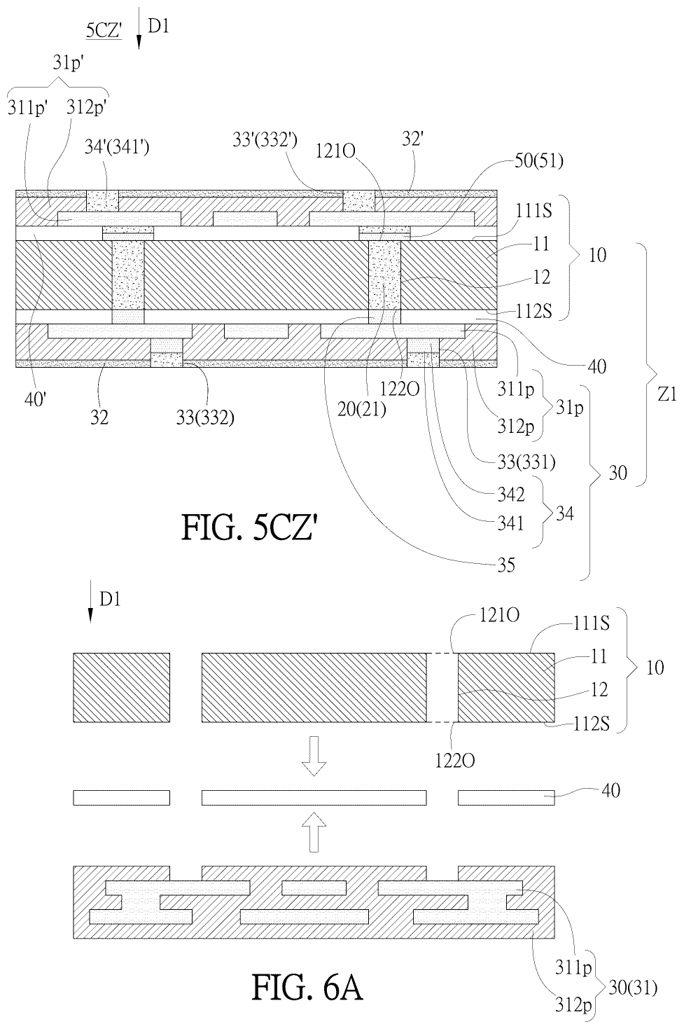

Referring an illustration in FIG. 4: Provide an associate adhesive structure 40′ on the other side of the core substrate 12.

To set an associate conductive layer structure 30′, referring in FIG. 4, on the other side of the core substrate 12, so that the core substrate 12 and the associate conductive layer structure 30′ are located on two opposite sides of the associate adhesive structure 40′ in a respective manner.

To connect the other end of the conductive member 20, referring in FIG. 4, to the associate conductive layer structure 30′ on the other side of the core substrate 10 through an opening window (not numerical) of the associate adhesive structure 40′.

At this embodiment of the method, a simple double-sided structure can be completed.

The above-mentioned conductive layer structure 30 and adhesive structure 40 can be patterned or unpatterned (, which is also described as undefined). The undefined conductive layers 30 and undefined adhesive layers 40 can achieve patterning effects through processes interspersed within or after them.

The conductive material mentioned above can complete the thermal curing process before the single-sided structure Z1 is finished. If an associate conductive layer structure 30′ is to be added to the other side, it can be combined with processes such as supplementing conductive material and its thermal curing to further achieve electrical connection the conductive layer structure 30 with the associate conductive layer structure 30′.

The conductive material can also undergo thermal curing after the single-sided structure Z1 is completed and after the associate conductive layer structure 30′is added to the other side, to simultaneously achieve electrical connection with the conductive layer structure 30/ associate conductive layer structure 30′.

The adhesive structure 40 mentioned above can be formed through a thermal pressing process of the conductive layer structure 30 and the core substrate 10. In this case, the adhesive structure (or adhesive layer) 40 can be a metal compound or metal transition material. It is worth noting that the terms “lamination,” “bonding,” and “joining” are used interchangeably and do not indicate any specific process, unless otherwise stated to the contrary in future argumentation.

The conductive layer structure 30 mentioned above is capable of being prepared in advance, or a patterning process can be implemented on the adhesive structure 40, or further combined with the core substrate 10.

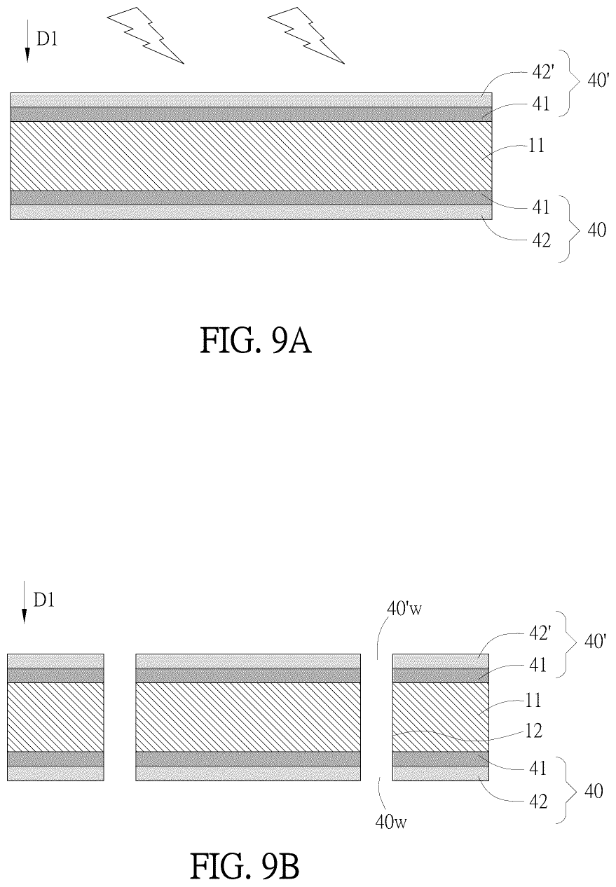

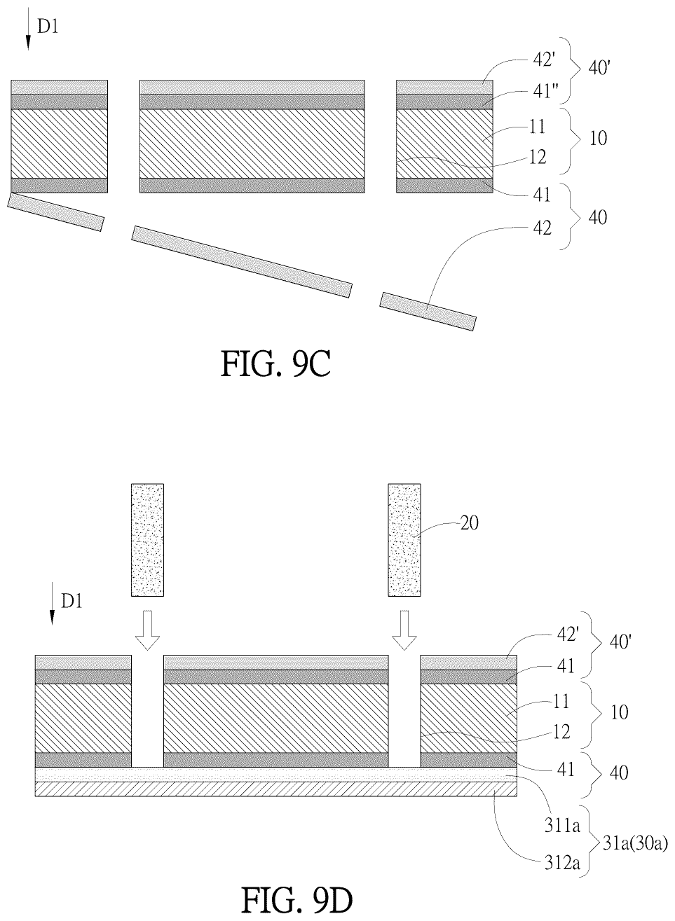

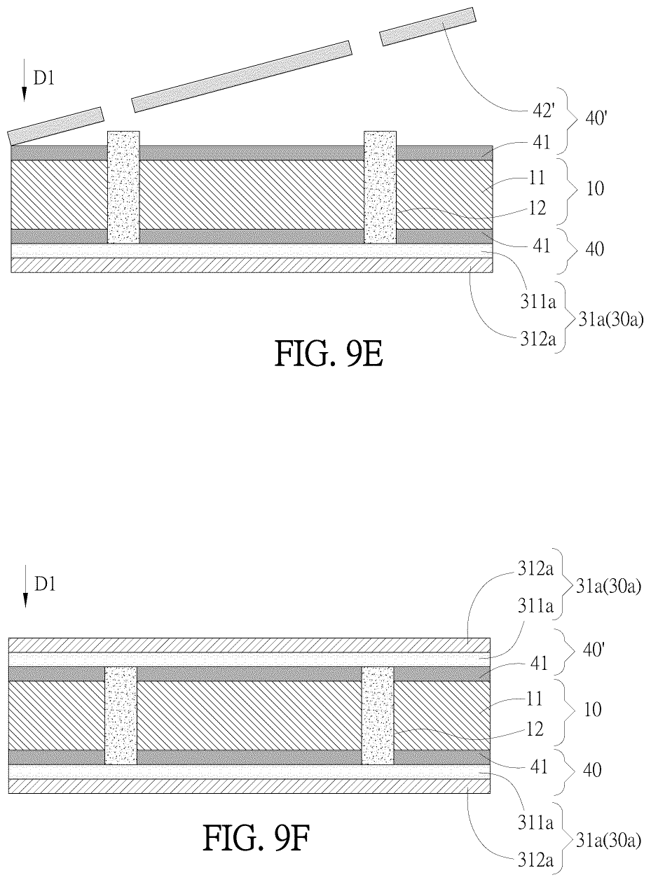

This disclosure also provides another method for manufacturing the electronic device, which can complete a double-sided structure simultaneously, referred in FIGS. 9A to 9F. In this case, a core substrate 11 without through holes is provided, referred to as an undefined initial substrate, as referred in FIG. 9A. The initial substrate 11 is first combined with one or two adhesive structure(s) 40 or 40′ as a whole, then a through hole 12 process is implemented, as referred in FIG. 9B, followed by providing at least one conductive layer structure 30a to at least partially cover at least one end of the through hole 12, as referred in FIG. 9C and FIG. 9D. At this point, two conductive layer structures 30a can be provided, as referred in FIG. 9E and FIG. 9F, one on each side of the core substrate 11, but still only at least partially covering one end of the through hole 12.

This process, taking two conductive layer structures as an example, includes at least the following steps: Preparing an undefined initial substrate 11. Stacking an adhesive structure 40 and an associate adhesive structure 40′ on opposite sides of the initial substrate 11, referred in FIG. 9A; wherein the adhesive structure 40 and the associate adhesive structure 40′each include an undefined adhesive layer 41, 41′ and a release layer 42, 42′; wherein the adhesive layer 41, 41′is located between the release layer 42, 42 and the initial substrate 10. Implementing a through hole process on the initial substrate 11 and its bonded adhesive structure 40 and associate adhesive structure 40′, referred in FIG. 9B; wherein the initial substrate 11 defines a through hole 12 to form a core substrate 10; the adhesive structure 40 and the associate adhesive structure 40′each define an opening window 40W, 40′W to form an adhesive pattern layer and an associate adhesive pattern layer respectively. Then, removing the release layer 42 of the adhesive structure 40, referred in FIG. 9C. Then, adding a conductive layer structure 30a to the adhesive pattern layer 41, with the conductive layer structure 30a covering at least a part of the corresponding through hole 12; and placing a conductive material in the through hole 12, referred in FIG. 9D. Then, removing the release layer 42′of the associate adhesive structure 40′, referred in FIG. 9E; placing an associate conductive layer structure 30a on the associate adhesive pattern layer 41′, referred in FIG. 9F. At the end, thermally curing the conductive material to form a conductive member 20; the conductive member 20 electrically connects to the conductive layer structure 30 and the associate conductive layer structure 30a at both ends through the corresponding opening windows 40W, 40′W.

To be noted, the process of implementing the through hole may include laser drilling, or laser modification and its wet etching process.

The electronic device disclosed herein has the following beneficial effects, including but not limited to: (1) A double-sided conductive structure with a glass substrate as the core substrate 10 can be easily completed. (2) Additionally, if the double-sided conductive pattern layer structure includes multiple layers of patterned conductive layers stacked together, it can further enhance integration and functional density. (3) An adhesive pattern layer can be further arranged between the conductive pattern layer structure and the core substrate. The adhesive pattern layer can be pre-combined with the conductive pattern layer structure and can be directly attached to the core substrate 10, thereby improving manufacturing efficiency. The opening window of the adhesive pattern layer can increase the contact area of the conductive member, thereby reducing contact resistance. (4) The various embodiments disclosed herein can be widely applied in semiconductor packaging, MEMS devices, display technology, RF circuits, optoelectronic integration, and other fields. For example, in OLED displays for pixel electrodes and driving circuits interconnection, in RF circuits for signal transmission and isolation, in MEMS sensors for multilayer structure interconnection, etc. This can effectively enhance the performance and functional density of electronic devices, offering significant technical and economic benefits. (5) The various embodiments disclosed herein can also be further combined with other technologies, such as combining with TSV technology for 3D integrated circuits, combining with FPC (Flexible Printed Circuit) technology for flexible electronic devices, and combining with MUF (Microfluidic Unit) technology for microfluidic devices, etc.

### Referring Different Substrate Materials

In addition to commonly used silicon-based substrates, examples can be given of inorganic substrates using single materials, composite materials, or compound materials such as glass, ceramic, glass-ceramic, sapphire, etc. Different substrate materials may require adaptation to different processing techniques, such as laser drilling, wet etching, dry etching, etc.

### Referring Different Conductive Layer Materials and Patterning Methods

Common conductive layer materials such as copper, aluminum, gold, etc., and different patterning methods such as wet etching, dry etching, electroplating, sputtering, electroless plating, vapor deposition, etc., can be listed. Different combinations of materials and methods can achieve different conductive properties and pattern precision.

### Referring Different Conductive Filling Materials and Filling Methods

In addition to commonly used copper electroplating filling, other conductive materials such as silver, gold, nickel, etc., can also be used. The filling methods can also be diversified, such as electrophoresis, electroplating, chemical plating, conductive paste filling, etc.

### Referring Special Shapes or Structures

In addition to commonly used circular through holes, other shapes such as square, elliptical, polygonal, etc., can also be included. Or there may be some special structural designs, such as blind holes (only one-sided opening), stepped holes (combination of multiple diameters), branch holes (multiple interconnected through holes), etc.

### First Implementation Example

As shown in FIG. 1, this implementation provides an electronic device 1, which includes a core substrate 10, a conductive component 20, a conductive layer structure 30, and an adhesive structure 40.

The core substrate 10 has a bare substrate 11 (referred as an undefined initial substrate) and defines two opposite surfaces 111S and 112S, as well as at least one through hole 12 that penetrates the upper and lower opposite surfaces 111S and 112S. The through hole 12 defines upper and lower openings 121O and 122O on the upper and lower surfaces 111S and 112S respectively. A projection direction D1 is defined perpendicular to one of the surfaces 111S or 112S of the core substrate. The conductive layer structure 30 is stacked on the core substrate 10 and is located on one side of the core substrate 10. For ease of explanation, in this implementation, the conductive layer structure 30 is located on the lower side of the core substrate 10 and covers at least a part of the lower opening 122O of the through hole 12. The conductive component 20 is located in the through hole 12 and is electrically connected at one end to the conductive layer structure 30.

### #Core Substrate

The core substrate 10 can be made from organic or inorganic materials. Organic materials include, but are not limited to, PI (Polyimide). Inorganic materials include, but are not limited to, silicon, glass, ceramic, glass-ceramic, or mixtures thereof. The core substrate 10 can be a single substrate, meaning it's not a composite layer substrate or a multi-layer substrate that's pressed/adhered together. The thermal expansion coefficient of the core substrate 10 can be in a range less than 17 ppm/° C., or in a range not greater than 30 ppm/° C. and not less than 17 ppm/° C.; to be noted, the criteria of the thermal expansion coefficient of the core substrate 10 may be equivalent to that of a non-single substrate. In typical implementations, there are multiple through holes 12 in the core substrate 10, with a corresponding number of conductive components 20.

### #Conductive Component

The conductive component 20 includes at least one conductive core 21. Additionally, the conductive component includes one of copper, silver, tin, and bismuth as a conductive material, or any combination of conductive materials. In one implementation, the conductive component 20 may further include resin material. In one implementation, regardless of whether it contains resin material or not, the conductive component 20 includes one or more conductive materials, wherein the volume of the mixture or alloy of conductive materials in the conductive component 20 is not less than 70% of the volume of the through hole. The upper and lower ends of the conductive component 20 can individually, but are not limited to, protrude from or be flush with the upper and lower openings 121O, 122O of the through hole 12 in the core substrate 10; protruding parts 21E′, referred in FIG. 1′, 1M′, 1X′, and 4X′, may be retained or flattened in subsequent processes.

It's worth noting that one method of forming the conductive component includes: printing, spraying, or planting a conductive material into the through hole 12, then providing a thermal curing process to the conductive material to form the conductive component 20; the conductive material includes metal paste, metal adhesive, metal wire, metal balls, metal rods, etc. After thermal curing, it may be necessary to add auxiliary conductive material to the aforementioned conductive component, which can be further thermally cured to form a conductive component assembly together with the conductive component; here, the conductive component assembly is equivalent to the conductive component 20 in the aforementioned method; this will not be repeated hereafter.

### #Conductive Layer Structure

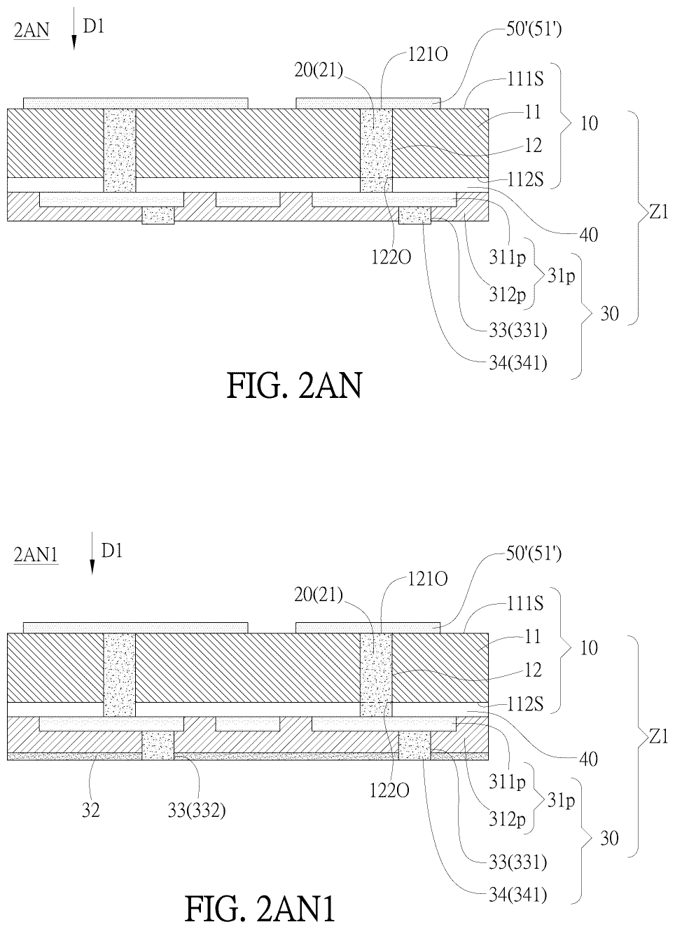

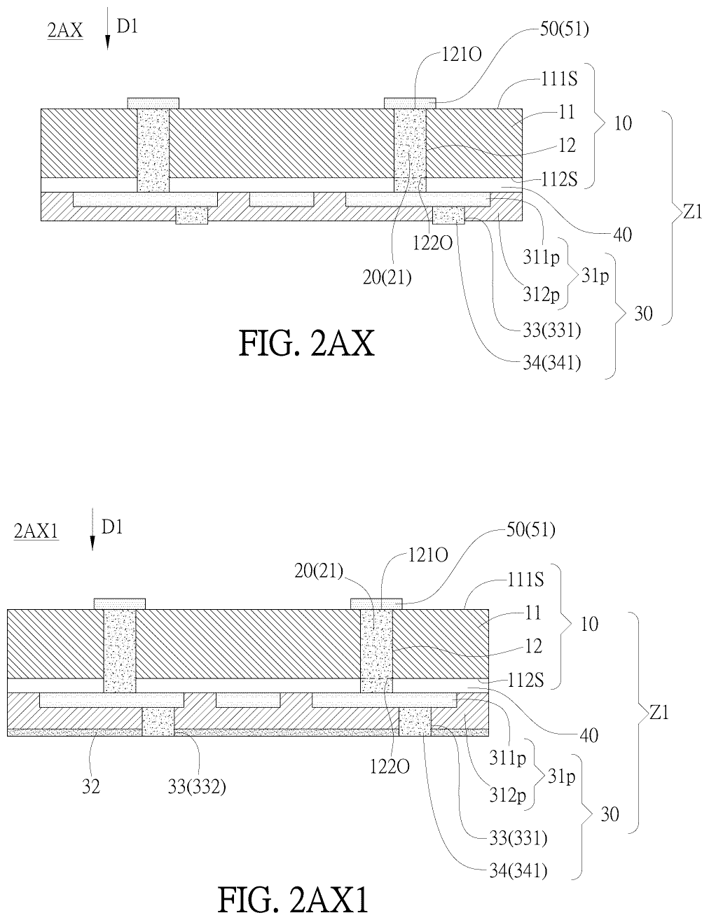

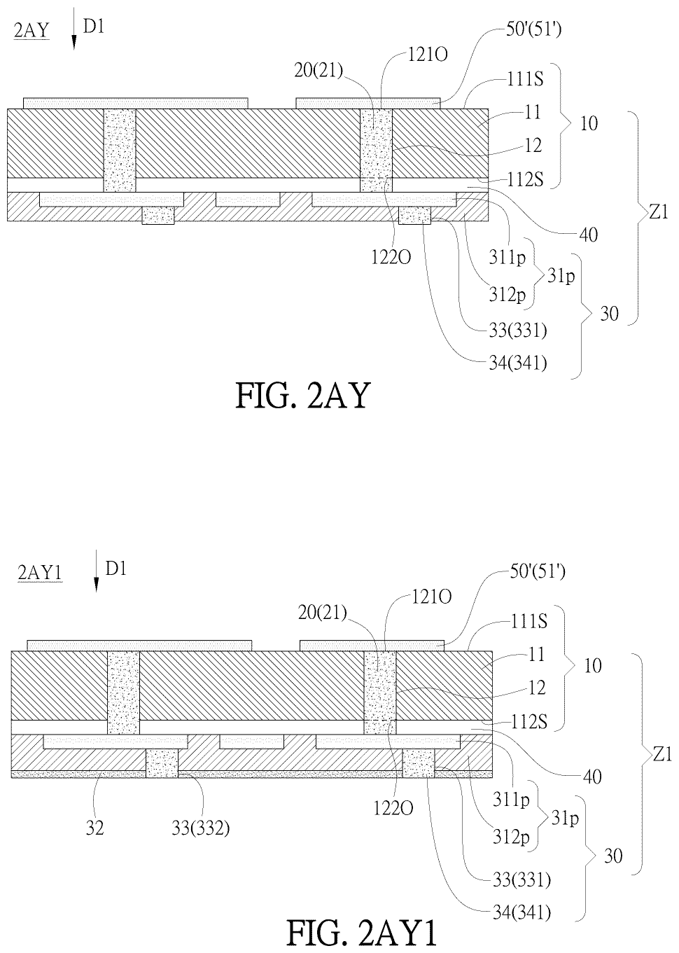

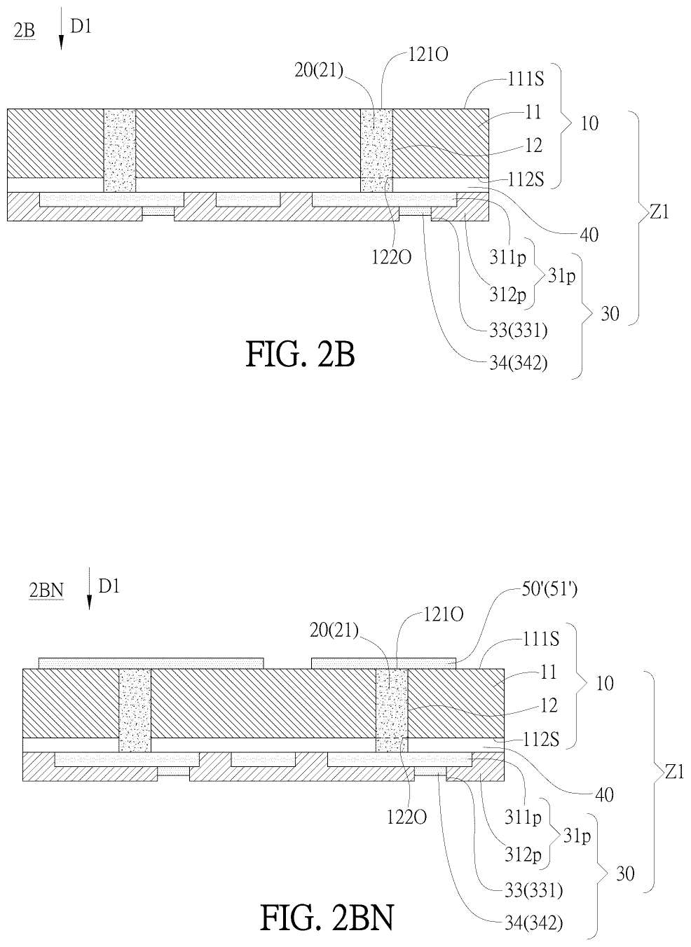

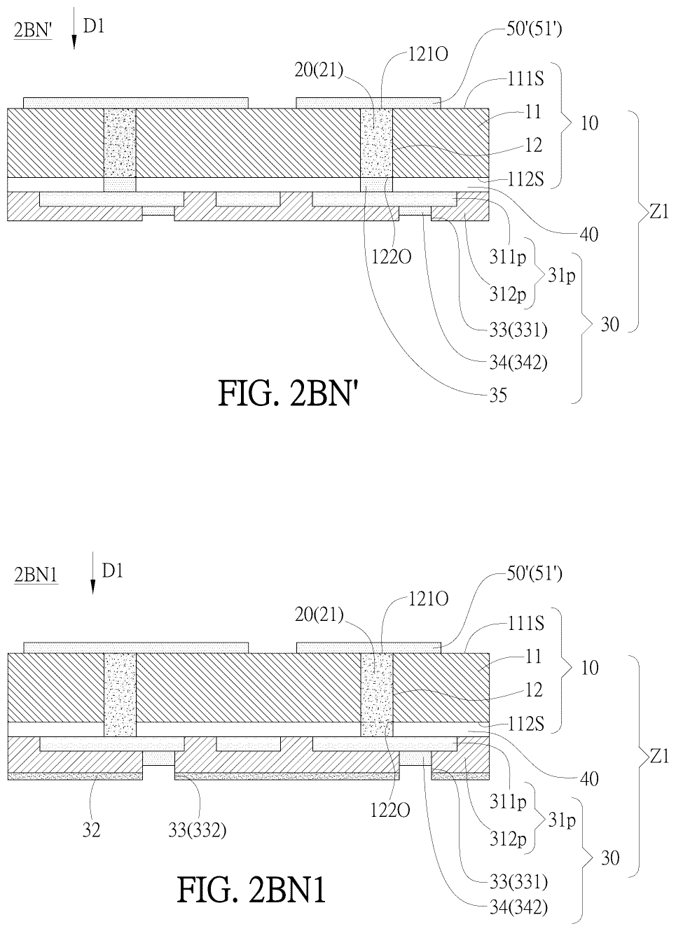

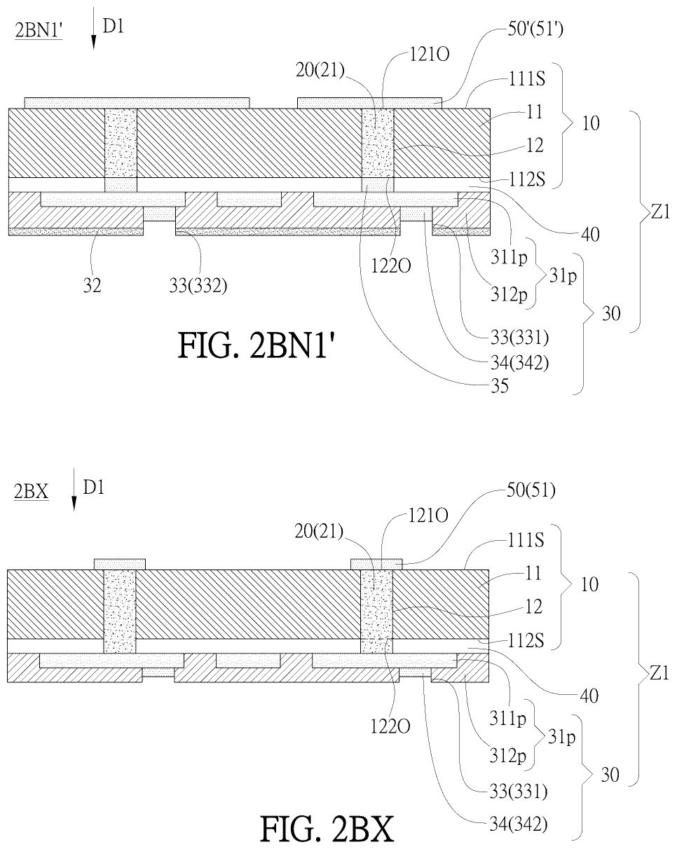

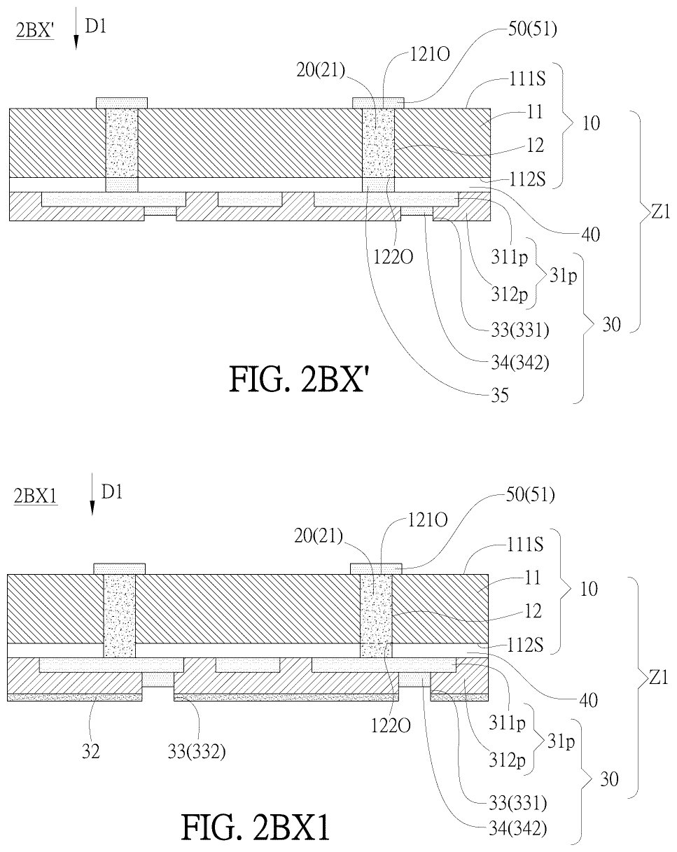

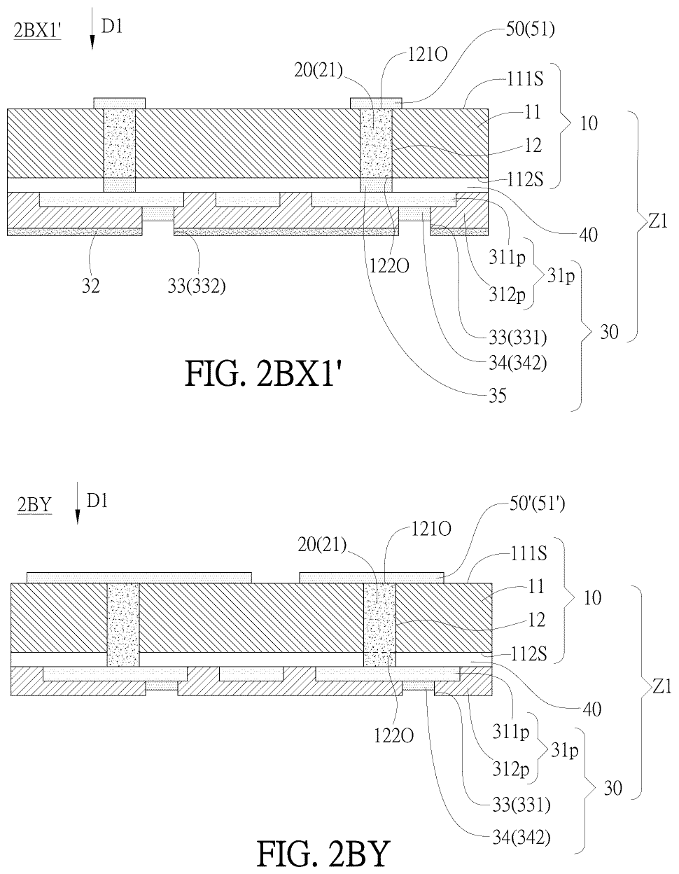

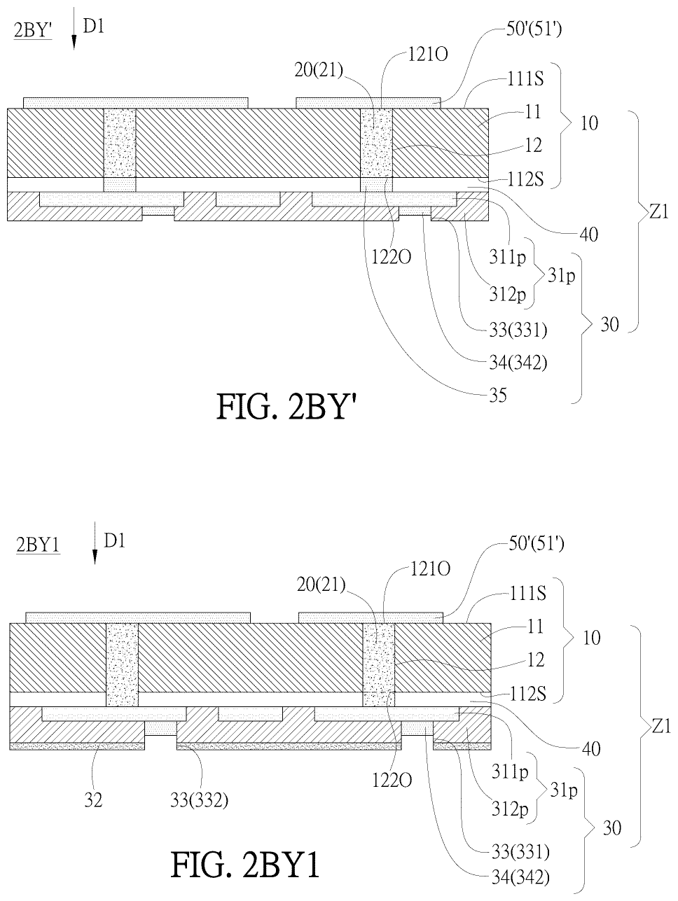

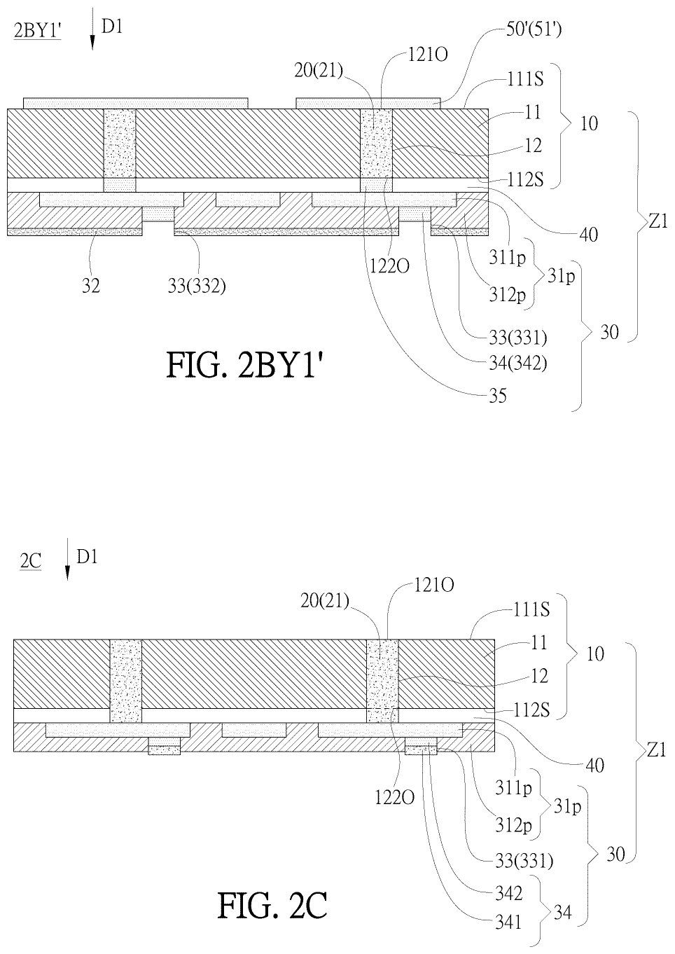

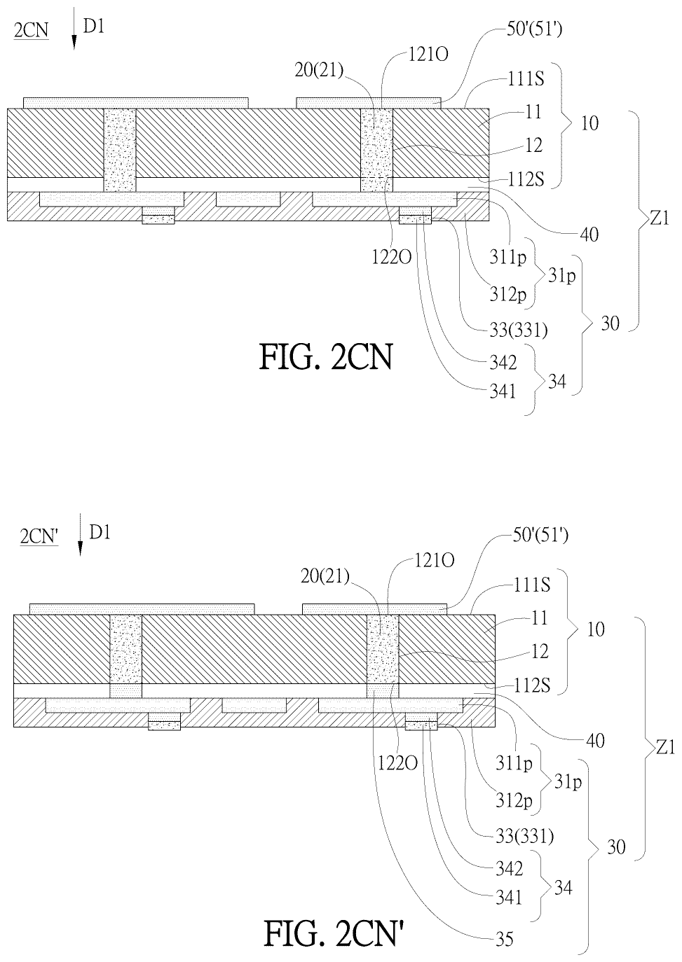

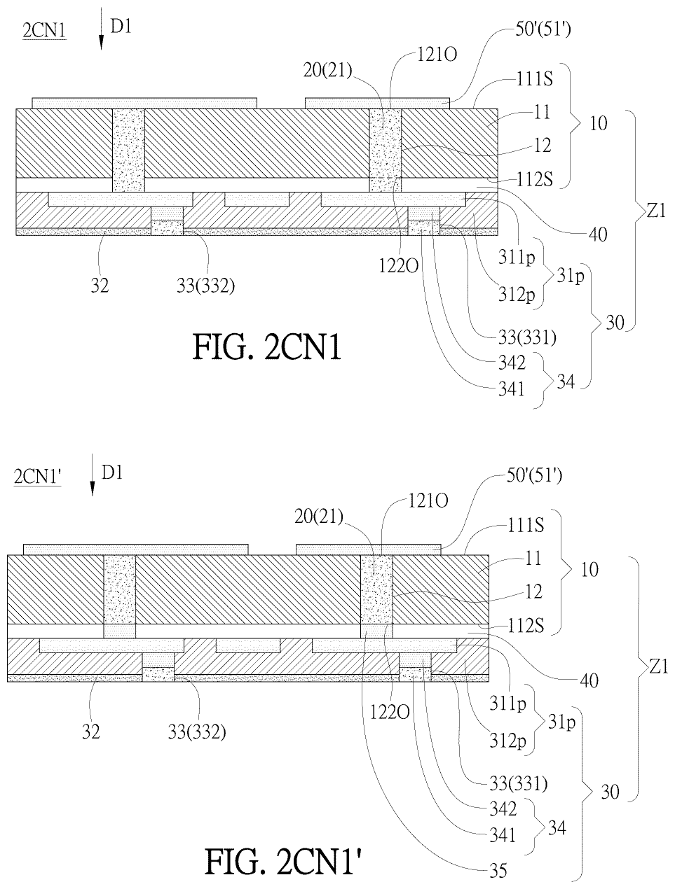

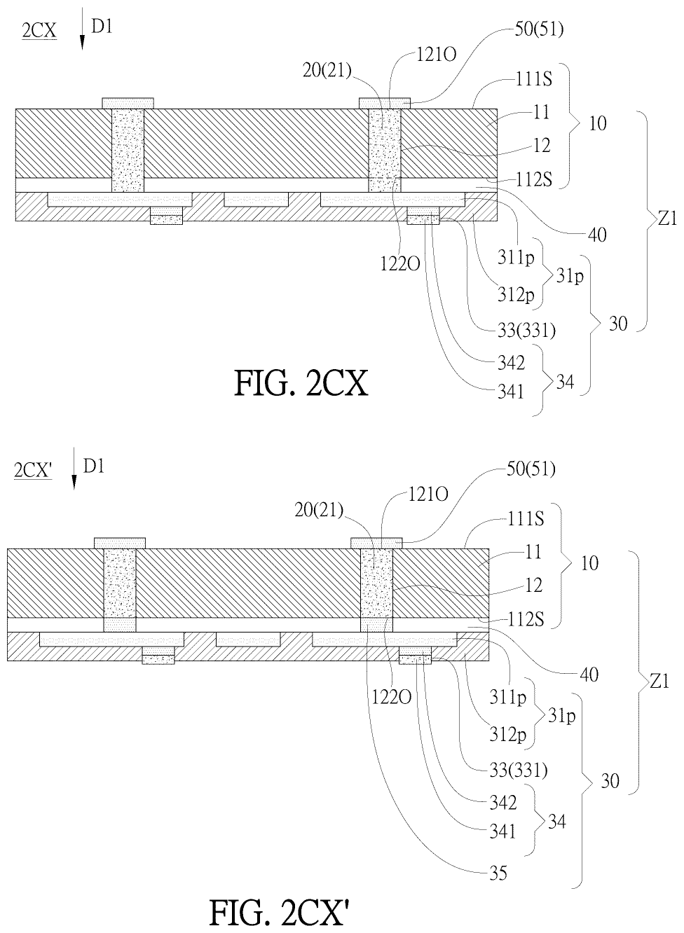

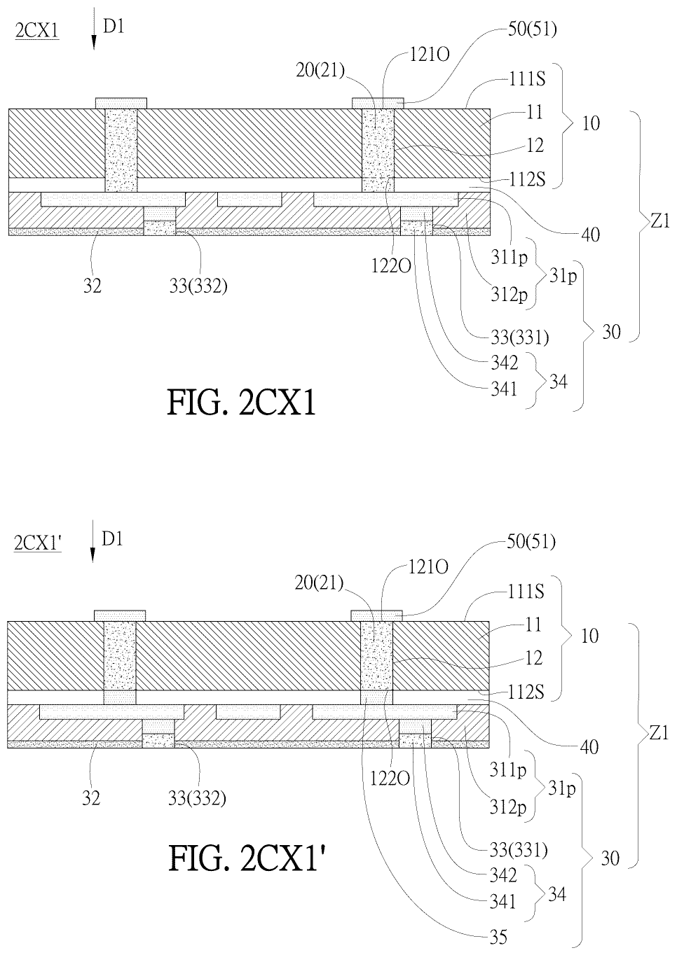

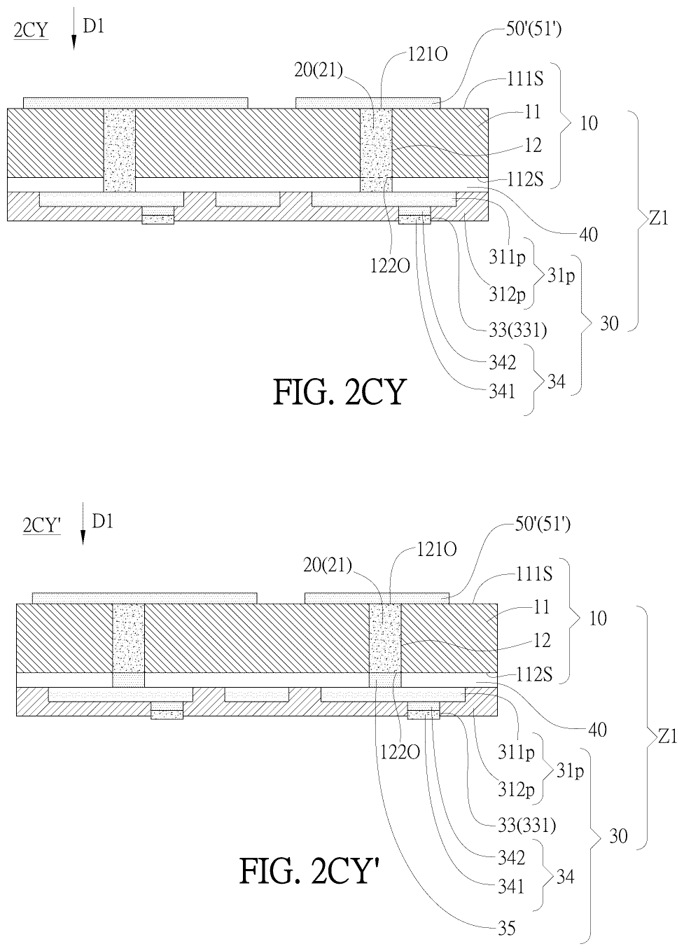

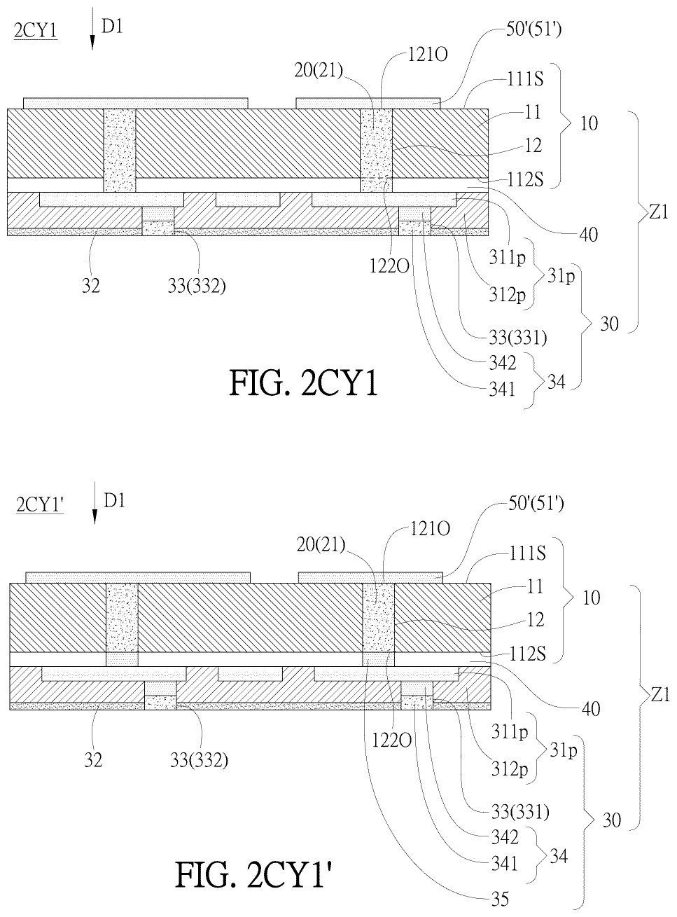

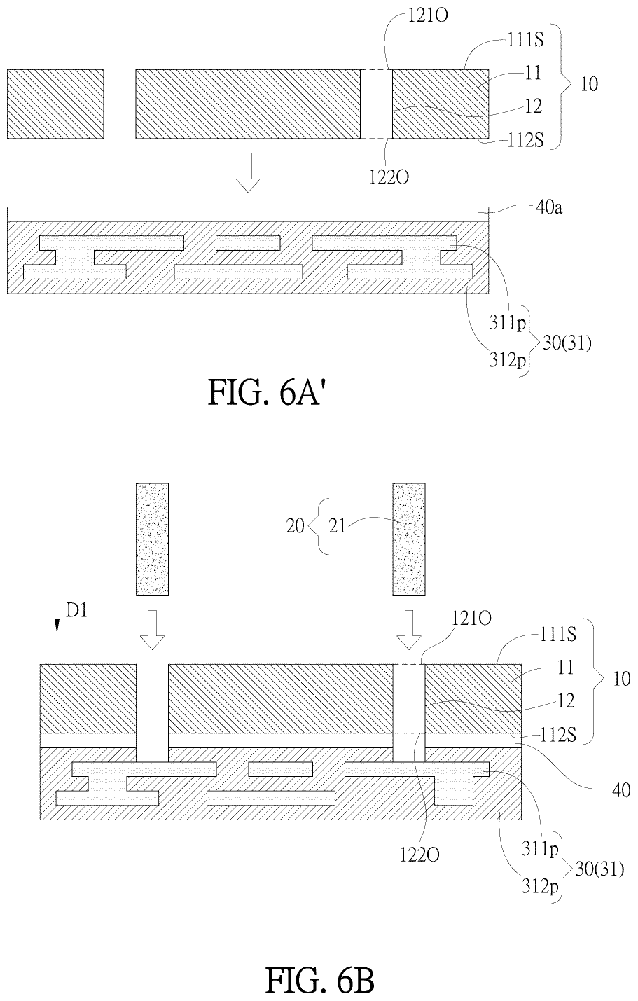

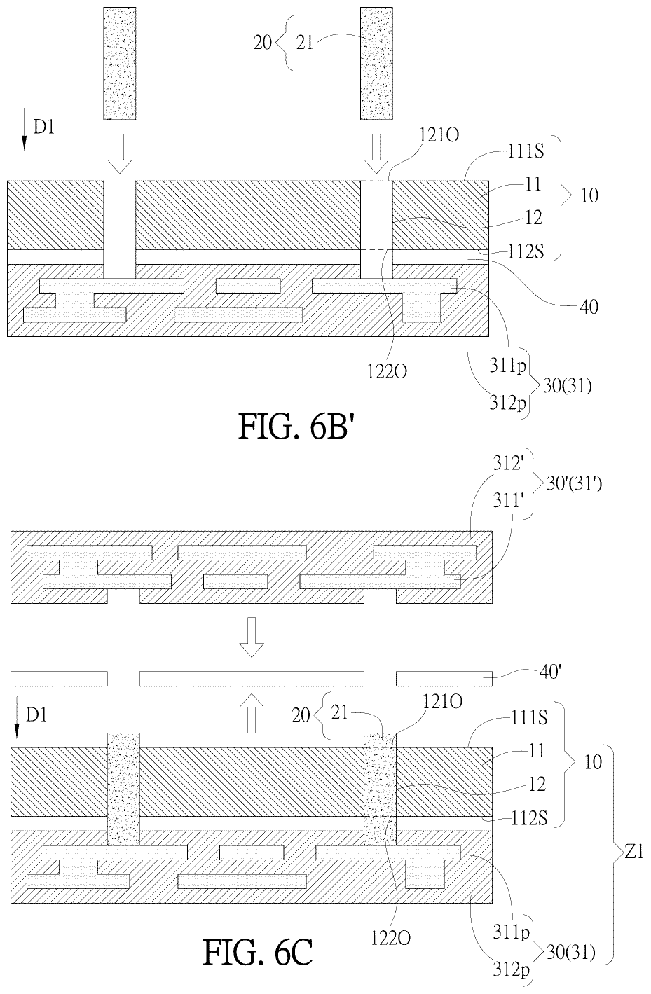

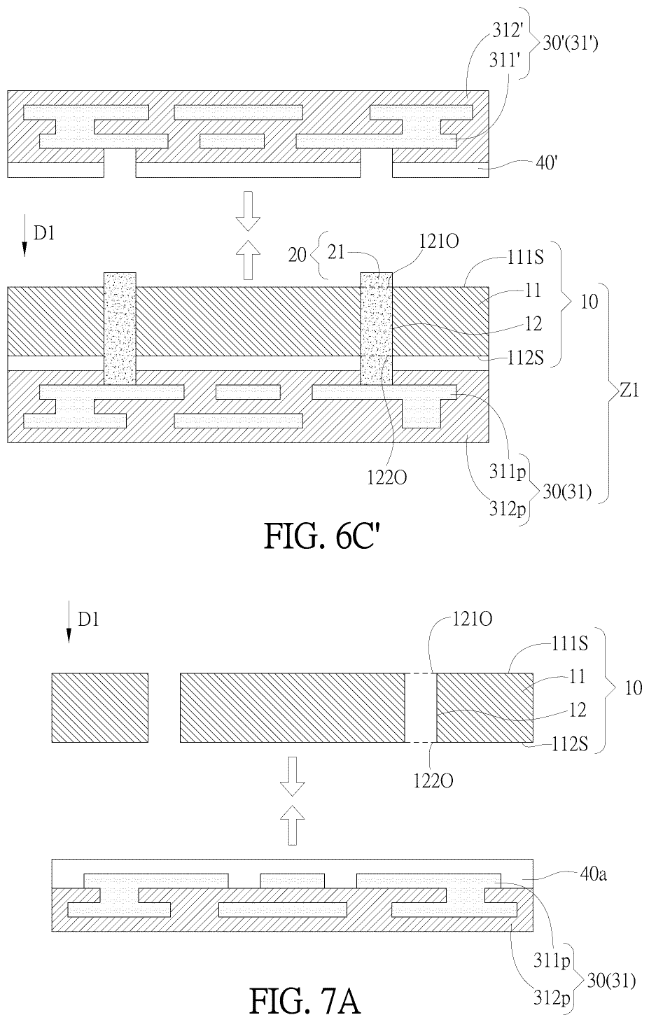

The conductive layer structure 30 includes at least one conductive structure 31, which includes a single layer or multiple layers of conductive layers 311. In one implementation, a single conductive layer 311 can be an unpatterned conductive layer, also called an undefined conductive layer, referred in FIG. 1, FIG. 1′, FIG. 1X, FIG. 1X′, and FIG. 1Y. In the case of undefined conductive layers 311, the conductive structure 31 further includes an insulating layer 312 arranged upon the conductive layer(s) 311. In another implementation, a single conductive layer 311 can be a patterned conductive layer, called a patterned conductive layer 311p, referred in FIGS. 2A to 2C, FIG. 2AX, FIG. 2BX, FIG. 2BX′, FIG. 2CX, FIG. 2CX′, FIG. 2AY, FIG. 2BY, FIG. 2BY′, FIG. 2CY, FIG. 2CY′, FIG. 2AN, FIG. 2BN, FIG. 2BN′, FIG. 2CN, and FIG. 2CN′. In yet another implementation, a conductive layer 311 can be multiple patterned conductive layers, such as illustration in FIGS. 6A to 6B, with at least two of these conductive layers electrically connected to each other. In the case of patterned conductive layers, the conductive structure 31p further includes an insulating layer 312p interwoven with the patterned conductive layer(s) 311p.

In the case of patterned conductive layers, the thickness of the conductive layer 311 can be less than 5 μm, or even smaller, for example, less than 3 μm or less than 1.5 μm.

In the case of undefined conductive layers, the thickness of the conductive layer 311 can be greater than 5 μm.

In one implementation, the conductive layer structure 30 further includes a base layer 32, illustrated in FIG. 2AN1, FIG. 2AX1, FIG. 2AY1, FIG. 2BN1, FIG. 2BN1′, FIG. 2BX1, FIG. 2BX1′, FIG. 2BY1, FIG. 2BY1′, FIG. 2CN1, FIG. 2CN1′, FIG. 2CX1, FIG. 2CX1′, FIG. 2CY1, FIG. 2CY1′, attached to the conductive structure 31; the base layer 32 and the core substrate 10 are on opposite sides of the conductive structure 31. This implementation of the base layer 32 is not limited to whether the conductive structure 31 has a single or multiple conductive layers 311, nor is it limited to whether the conductive layer 311 is patterned or undefined.

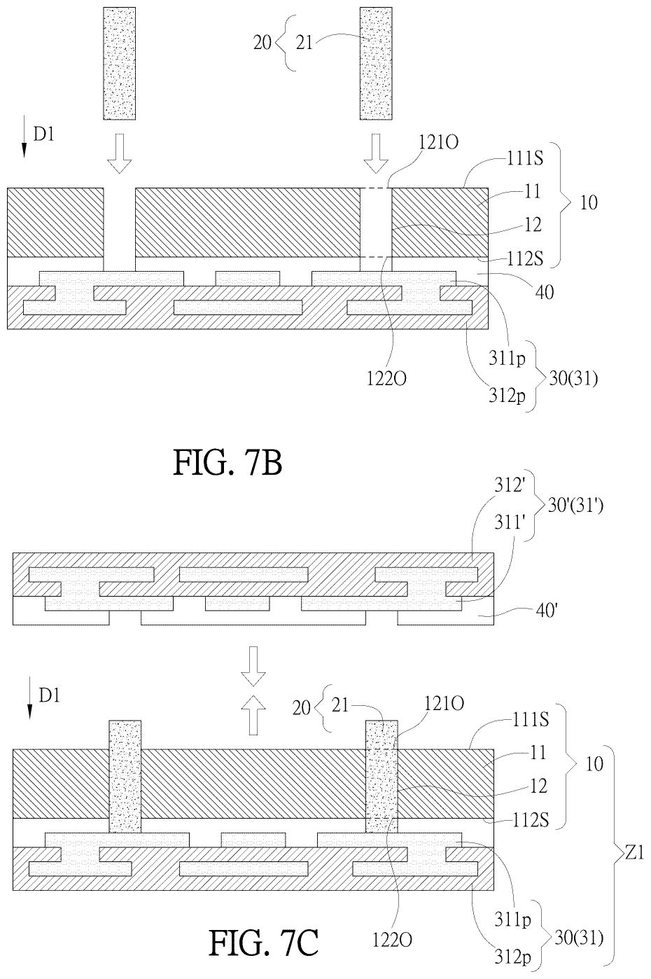

For ease of explanation and to avoid misunderstanding, in the following implementations, the conductive layer structure 30 is mostly exemplified by the conductive structure 31 having multiple layers of patterned conductive layers 311p stacked in the projection direction D1, and multiple layers of insulating layer 312p arranged alternately with these patterned conductive layers 311p; but it is not limited to multiple layers of patterned conductive layers 311p and insulating layer 312p, referred in FIGS. 6A to 6C, FIGS. 7A to 7C, FIG. 6A′ to 6C′.

It's worth noting that these patterned conductive layers 311p are stacked parallel to each other, and multiple conductive structures (not drawn) can electrically connect adjacent or non-adjacent two patterned conductive layers 311p. Although these insulating layers 312p are arranged in multiple layers, they can use the same material and can be viewed as a whole; however, in description, this structure is still expressed as a multi-layer configuration. These insulating layers 312p may include PI, Silicon Nitride, Silicon oxides, Alumina (Aluminum Oxide), Aluminum Nitride, Silicon Carbide, Magnesia (Magnesium Oxide), Titania (Titanium Oxide), Lead Zirconate Titanate (PZT), epoxy resin material, or any combination of the aforementioned materials.

The mentioned conductive layer structure 30 is bonded to the core substrate 10 through an adhesive structure (adhesive pattern layer) 40, with the conductive layer 311 adjacent to the core substrate 10 stacked towards the core substrate 10. The conductive layer structure 30 can also be stacked with the insulating layer 312 adjacent to the core substrate 10 facing towards the core substrate 10. In this case, the conductive layer 311 is exposed to the through hole 12 of the core substrate 10 and is electrically connected to the conductive component 20. At this time, the adhesive structure (adhesive pattern layer) 40 includes organic materials. It's worth noting that in the case of a single conductive layer 311, different conductive components 20 are all electrically connected to the t conductive layers 311; while in the case of multiple patterned conductive layers 311p, different conductive components 20 can be electrically connected to the same or different patterned conductive layers 311p. At this time, one end of the conductive component 20 located at the lower opening 122O of the through hole 12 in the core substrate 10 can protrude from or be flush with the lower opening 122O of the through hole 12 in the core substrate 10. In other words, the conductive component 20 can further extend in the projection direction D1 into the conductive layer structure 30; specifically, the conductive component 20 can further extend in the projection direction D1 into one of the patterned conductive layers 311p within the conductive layer structure 30. It's worth noting that the conductive component 20 extending into one of the patterned conductive layers 311p means that at least one layer of insulating layer 312p has an area defined corresponding to the through hole 12 of the core substrate 10; the same or similar concept will not be repeated. Ones of the differences in FIGS. 6A to 6C, FIGS. 7A to 7C, and FIG. 6A′ to 6C′ are how the conductive component 20 extends. In FIGS. 6A to 6C, and FIG. 6A′ to 6C′, the one of the patterned conductive layers 311p where the conductive component 20 reaches is embedded in the insulating layer 312p. In FIGS. 7A to 7C, the one of the patterned conductive layers 311p where the conductive component 20 reaches is a conjunction between the adhesive structure 40 and the insulating layer 312p.

Another Differences in FIGS. 6A to 6C, FIGS. 7A to 7C, and FIG. 6A′ to 6C′ are when the adhesive structure 40 attaches to the core substrate 10. In FIGS. 6A to 6C, and FIGS. 7A to 7C, the adhesive structure 40, the associate adhesive structure 40′, the ore substrate 10, the conductive layer structure 30 and the conductive layer structure 30′ are individual from each other. The adhesive structure 40, the ore substrate 10, the conductive layer structure 30 are laminated simultaneously, and its semi-production is then further laminated with the associate adhesive structure 40′ and the conductive layer structure 30′. In FIG. 6A′ to 6C′, the adhesive structure 40 and the associate adhesive structure 40′ are respectively attached to the conductive layer structure 30 and the conductive layer structure 30′, and then laminated to the core substrate 10 in orders. Here, the adhesive structure 40 is also an adhesive pattern layer because it has already formed an opening window 40W.

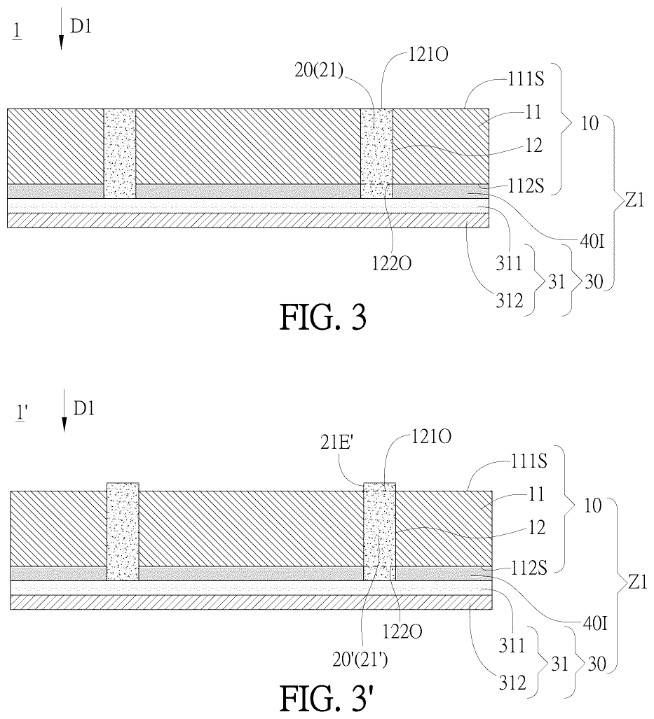

The mentioned conductive layer structure 30 can also be directly laminated onto the core substrate 10. In this case, the adhesive pattern layer 40I is simultaneously produced during lamination. The adhesive pattern layer 40I may include metal compounds (such as copper oxide (CuO or Cu₂O)) or metal transition materials (such as copper transition layer); as shown in FIG. 3 and FIG. 3′.

In the mentioned conductive layer structure 30, the material of the single or multiple conductive layers 311, 311p can include one of the conductive materials such as aluminum, copper, or any combination of conductive materials. The form of the single layer of the conductive layer 311 can be a metal foil, for example: a metal foil formed by rolling (such as copper foil), or a metal foil gradually formed by electrolysis, electroplating, electroless plating, sputtering, or vapor deposition.

In another description for this implementation of the electronic device 1, the core substrate 10 with through holes 12 is first prepared, and the conductive layer structure 30 covers at least a part of the lower opening 122O of the through hole 12. Then, the conductive component 20 is placed into the through hole 12, with its upper end left open for electrical connection to other components or devices, while its lower end is electrically connected to the conductive layer structure 30. At this time, the conductive layer structure 30, in addition to having the conductive structure 31, may further include its own base layer 32, illustrated in FIG. 2AN1, FIG. 2AX1, FIG. 2AY1, FIG. 2BN1, FIG. 2BN1′, FIG. 2BX1, FIG. 2BX1′, FIG. 2BY1, FIG. 2BY1′, FIG. 2CN1, FIG. 2CN1′, FIG. 2CX1, FIG. 2CX1′, FIG. 2CY1, FIG. 2CY1′. This base layer 32 can be partially or completely removed after the conductive layer structure 30 at least partially overlaps the lower opening 122O of the through hole 12. Removal methods include peeling off, laser removal, thermal removal, mechanical removal, etc.

In the mentioned conductive layer structure 30, there is also an external linking hole 33 that exposes at least a part of the corresponding conductive layer. This external linking hole 33 at least includes the through via 331 in the insulating layer 312, 312p, illustrated in FIG. 2AX, FIG. 2BX, FIG. 2BX′, FIG. 2CX, FIG. 2CX′, FIG. 2AY, FIG. 2BY, FIG. 2BY′, FIG. 2CY, FIG. 2CY′, FIG. 2AN, FIG. 2BN, FIG. 2BN′, FIG. 2CN, and FIG. 2CN′.

This external linking hole 33 includes the through via 331 in the insulating layer 312p, and the external linking hole further includes a via 332 in the base layer 32 (or a remaining part of the base layer) illustrated in FIG. 2AN1, FIG. 2AX1, FIG. 2AY1, FIG. 2BN1, FIG. 2BN1′, FIG. 2BX1, FIG. 2BX1′, FIG. 2BY1, FIG. 2BY1′, FIG. 2CN1, FIG. 2CN1′, FIG. 2CX1, FIG. 2CX1′, FIG. 2CY1, FIG. 2CY1′. The via 332 in the base layer 32 can at least partially overlap with the through via 331 in the insulating layer 312, allowing at least a part of the conductive layer 311 to be exposed through the via 332 and the through via 331. It's worth noting that the via 332 in the base layer 32 can also directly correspond to and electrically connect to the conductive layer 311, without needing to communicating with the through via 331 in the insulating layer 312.

The conductive layer structure 30, in addition to having the conductive structure 31, also includes its own base layer 32. The substrate can be a multi-layer substrate, partially removed to retain part of the base layer 32. In this case, the base layer 32 includes at least a first base layer (not shown) attached to the conductive structure, and a second base layer (not shown) attached to the first base layer. The second base layer and the conductive structure are on opposite sides of the first base layer. After removing the second base layer, the first base layer can be retained. The first base layer can be, but is not limited to, PI (polyimide), while the second base layer can be or include, but is not limited to, at least one of glass, or ceramic, and glass-ceramic material. The first base layer or the entire base layer 32 can also be or include, but is not limited to, at least one of PI, glass, or ceramic, and glass-ceramic material.

The process of the external linking holes includes at least one of the following processes: laser drilling, or laser modification followed by wet etching. The process of forming materials within the external linking holes includes at least one of the following processes: photolithography etching (photoresist imaging), laser direct imaging (LDI), and vacuum heating evaporation process.

In the mentioned conductive layer structure 30, there is also an external conductive structure 34, installed in the external linking hole 33, electrically connected to the corresponding conductive layer. This is used to provide external electrical connections for the conductive layer structure 30.

The external conductive structure 34 further has a surface treatment layer 342 set on the corresponding conductive layer. The surface treatment layer 342 includes one or any combination of conductive materials such as copper, nickel, gold, silver, chromium, titanium, tungsten, tin. The surface treatment layer 342 can serve as a solder pad, including but not limited to ENIG (Electroless Nickel Immersion Gold).

The external conductive structure 34 further has an external conductive member 341, shown in FIGS. 2A, 2AN, 2AN1, 2AX, 2AX1, 2AY, 2AY1, 2C, 2CN, 2CN′, 2CN1, 2CN1′, 2CX, 2CX′, 2CX1, 2CX1′, 2CY, 2CY′, 2CY1, and 2CY1′, installed and electrically connected to the corresponding conductive layer; or, the external conductive structure 34 further has an external conductive member 341 installed and electrically connected to a surface treatment layer 342 shown in FIGS. 2A, 2AN, 2AN1, 2AX, 2AX1, 2AY, 2AY1, 2C, 2CN, 2CN′, 2CN1, 2CN1′, 2CX, 2CX′, 2CX1, 2CX1′, 2CY, 2CY′, 2CY1, and 2CY1′. The external conductive member 341 includes, but is not limited to, conductive balls, such as solder balls. The surface treatment layer 342 may be implemented without the external conductive member 341, shown in FIGS. 2B, 2BN, 2BN′, 2BN1, 2BN1′, 2BX, 2BX′, 2BX1, 2BX1′, 2BY, 2BY′, 2BY1, and 2BY1′.

The conductive layer structure further includes a surface treatment layer 35, shown in FIG. 2BN', 2BN1′, 2BX′, 2BX1′, 2BY′, 2BY1′, 2CN′, 2CN1′, 2CX′, 2CX1′, 2CY′, and 2CY1′, located within the opening window (without numerals) and electrically connected to the corresponding conductive layer 30, 30a, used for connecting the conductive component 20. This surface treatment layer 35 includes one or any combination of conductive materials such as copper, nickel, gold, silver, chromium, titanium, tungsten, tin.

The mentioned conductive component 20 can further extend into the conductive layer structure 30. Generally, it would extend in the projection direction, but the directionality of the three-dimensional structure has many possibilities and is not limited to this.

The mentioned conductive layer structure 30 can contact the adhesive structure 30 with either conductive or insulating layers. Generally speaking, when directly bonding to an undefined metal layer, it would contact the adhesive structure 30 with conductive materials. When bonding to a pre-prepared conductive layer structure 30, it would contact the adhesive structure 30 with insulating layers. The above are only examples and are not limited to these scenarios.

For schematic diagrams of the above-mentioned various embodiments, please refer to respectively: FIGS. 2A, 2B, and 2C; FIG. 2AX, 2BX, 2CX, 2BX′, and 2CX′; FIG. 2AY, 2BY, 2CY, 2BY′, and 2CY′; FIG. 2AN, 2BN, 2CN, 2BN′, and 2CN′; FIG. 2AX1, 2BX1, 2CX1, 2BX1′, and 2CX1′; FIG. 2AY1, 2BY1, 2CY1, 2BY1′, and 2CY1′; FIG. 2AN1, 2BN1, 2CN1, 2BN1′, and 2CN1′.

When the adhesive layer 40 is made of organic material, the mentioned conductive component 20 at least partially contacts this adhesive layer 40.

Referred in FIG. 1M, FIG. 1M′, and FIG. 4′, the mentioned conductive component 20′ has a conductive core 21′and a conductive interface layer 211E′. The conductive core 21′ can be located in the through hole 12, while the conductive interface layer 211E′ electrically connects the conductive core 21′ and the conductive layer structure 30. The conductive interface layer 211E′ extends along the surface of the core substrate 10 corresponding to the conductive layer structure 30 (i.e., the lower surface 112S), and is located in the opening window 40W of the adhesive layer 40, as shown in FIGS. 1M and 1M′. The conductive interface layer 22 spreads out horizontally parallel to the core substrate 10 and can contact at least a part of the conductive layer structure 30. The conductive interface layer 22 can increase the contact area between the conductive component 20A and the conductive layer structure 30, which can bring the advantage of reducing contact resistance. The opening window of the adhesive layer 40 can be larger than the through hole 12, allowing the conductive component 20 to develop conductive interface layers 22, 22′. The opening window of the adhesive layer 40 can be formed in advance before bonding, or formed after bonding using laser (or other processes).

Additionally, the conductive core 21 or its conductive interface layer 22 can further extend to one of the conductive layers 311.

The conductive core 21′and the conductive interface layer 211E′ can be made of the same material.

The other end of the mentioned conductive component 20 can be in an open state. This other end of the conductive component can protrude from the other side of the core substrate, as shown in FIG. 1′and 1M′. Alternatively, an external conductive layer 50 (51), 50′ (51′) can be implemented at the other end of the conductive component, as shown in FIGS. 1X, 1X′, 1Y, 2AN, 2AN1, 2AX, 2AX1, 2AY, 2AY1, 2BN, 2BN′, 2BN1, 2BN1′, 2BX, 2BXΔ, 2BX1, 2BX1′, 2BY, 2BY′, 2BY1, 2BY1′, 2CN, 2CN′, 2CN1, 2CN1′, 2CX, 2CX′, 2CX1, 2CX1′, 2CY, 2CY′, 2CY1, 2CY1′. This external conductive layer includes one or any combination of conductive materials such as copper, silver, nickel, gold, tin, and bismuth.

When the external conductive layer is a patterned external conductive layer 50 (51), 50′ (51′), it can further expand upward with other conductive layer structures, such as shown in FIG. 1Y. The external conductive layer may include more than one layer, such as a first external conductive layer 51 and a second external conductive layer 52, shown in FIG. 4X′, 5AX, 5AZ, 5BX, 5BX', 5BZ, 5CX, 5CX′, 5CZ, and 5CZ′. The external conductive layer 50x may include more than one layer, such as a second external conductive layer 52 including external conductive layers 52x and an insulation layer 52y interwoven with the external conductive layers 52x.

### Second Embodiment

The second embodiment is essentially a combination and arrangement of various structures from the first embodiment. The electronic device further extends the associate adhesive structure 40′ and the associate conductive layer structure 30′ to the upper surface 111S side of the core substrate 10. This can partially or completely cover (or not cover) the upper opening 121O of the through hole 12 in the core substrate 10. The associate adhesive structure 40′ is positioned between the associate conductive layer structure 30′ and the core substrate 10. However, the associate conductive layer structure 30′ must still electrically connect to the other end of the conductive component 20 (i.e., the end at the upper opening 121O of the through hole 12 in the core substrate 10). The associate conductive layer structure 30′ can be a structural layer that is symmetrical or asymmetrical to the conductive layer structure 30, with similar or dissimilar functions. The associate conductive layer structure 30′ can have various forms similar to those covered by the conductive layer structure 30, including external linking holes and external conductive structures, which will not be elaborated on further.

The various aspects of the above-mentioned embodiments can be arranged and combined.

Due to the different manufacturing processes for the various embodiments mentioned above, the main commonalities are as follows: First, prepare the core substrate 10. The core substrate 10 has through holes 12 either before or after bonding the adhesive structure 40, and the conductive layer structure 30 at least partially covers the through holes 12 (taking the lower opening 122O as an example). Afterwards, the conductive components 20 are respectively placed into the through holes 12, thereby electrically connecting to the conductive layer structure 30.

For ease of understanding, parts of the process are extracted as examples and illustrated as follows:

FIGS. 6A to 6C illustrate how the conductive layer structure 30 and the associate conductive layer structure 30′are combined with the core substrate 10 through the adhesive structure 40 and associate adhesive structure 40′, respectively. Here, we do not distinguish which component is the passive or active bonding body.

It's worth elaborating that in the step of arranging the conductive component 20 in the structural assembly 100, it can be done through printing, spraying, coating, or planting a conductive material. The conductive material can be conductive glue/paste, conductive wire (e.g., gold wire or copper wire), conductive ball (e.g., gold ball, tin ball), or conductive column/rod, etc. This is just for illustration. This method requires a further thermal curing process to solidify the conductive material to form the conductive component 20. The thermal curing process can occur between FIGS. 6B and 6C (and also after FIG. 6C), or it can uniformly occur after FIG. 6C.

Before FIG. 6C, the conductive component 20 can be further planarized so that the exposed end can be flush with the corresponding surface of the core substrate 10.

In this embodiment, the structure of the conductive layer 30 is exemplified by multiple insulating layer layers and multiple conductive layers, which will not be elaborated on further.

FIG. 6A′ to 6C′ illustrate a variation where the adhesive structure is first combined with the conductive layer structure.

One of the more noteworthy embodiments, which also serves as a reference for how to implement undefined conductive layers and how to derive conductive layer structures.

A core substrate 10 with a through hole 12 has a conductive layer structure 30a attached to one surface 112S. At this point, the conductive layer structure 30a has a conductive structure 31a and a base layer 32a. The conductive structure 31a has an undefined conductive layer 311a, which at least partially covers the through hole 12 of the core substrate 10. Here, the form of the undefined conductive layer 311a can be a metal foil, for example: a metal foil formed by rolling (such as copper foil).

After closing one end 122O of the through hole 12 in the core substrate 10, the hole is filled, using the process of printing conductive material 83 as an example. Then, provide an associate conductive structure 31a′, which also has an undefined conductive layer 311a′, used to at least partially cover the other end 121O of the through hole 12 in the core substrate 10.

When both ends of the through hole 12 in the core substrate 10 are at least partially covered, perform a thermal curing process. At this time, the conductive material 83 can be transformed into a conductive component 20 and electrically connected to the undefined conductive layer 311a of the conductive structure 31 and the undefined conductive layer 311a′ of the associate conductive structure 31a′ respectively.

After completing the cured structure, remove the base layers 32a, 32a′; if removed separately, the order doesn't matter.

A temporary double-sided structure Z2 can be obtained, at this point the double-sided structure Z2 still maintains a state where the conductive layers on both sides are undefined.

Then, perform a patterning process on the undefined conductive layer 311a of the conductive structure 31 and the undefined conductive layer 311a′ of the associate conductive structure 31a′, which can include methods such as exposure etching, laser direct imaging, vacuum thermal evaporation, etc.

Please note that in this disclosure, if there is no differentiated marking for the labels, it should not affect the understanding of this disclosure.

Afterwards, further complete the external linking holes and external conductive structures. The completion of these two sets of external conductive structures can be done in any order.

It's worth noting that the semi-finished or finished products of each step mentioned above can be subjects of market transactions, which will not be elaborated here.

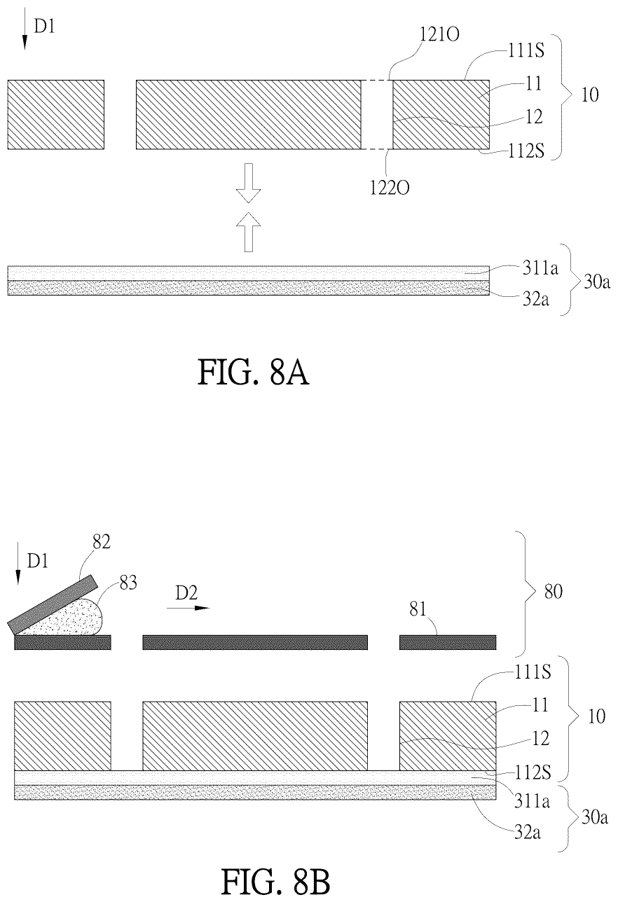

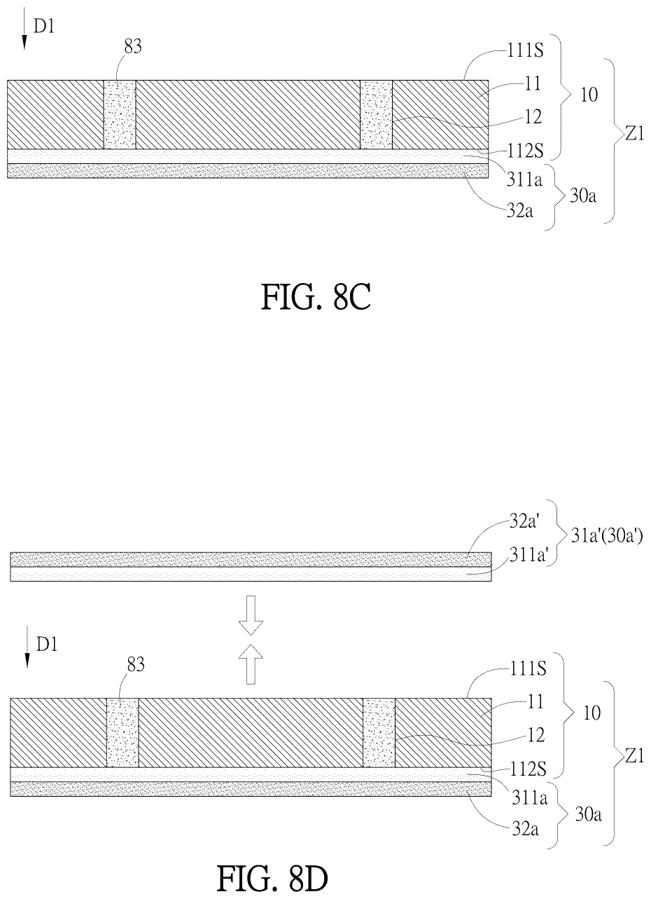

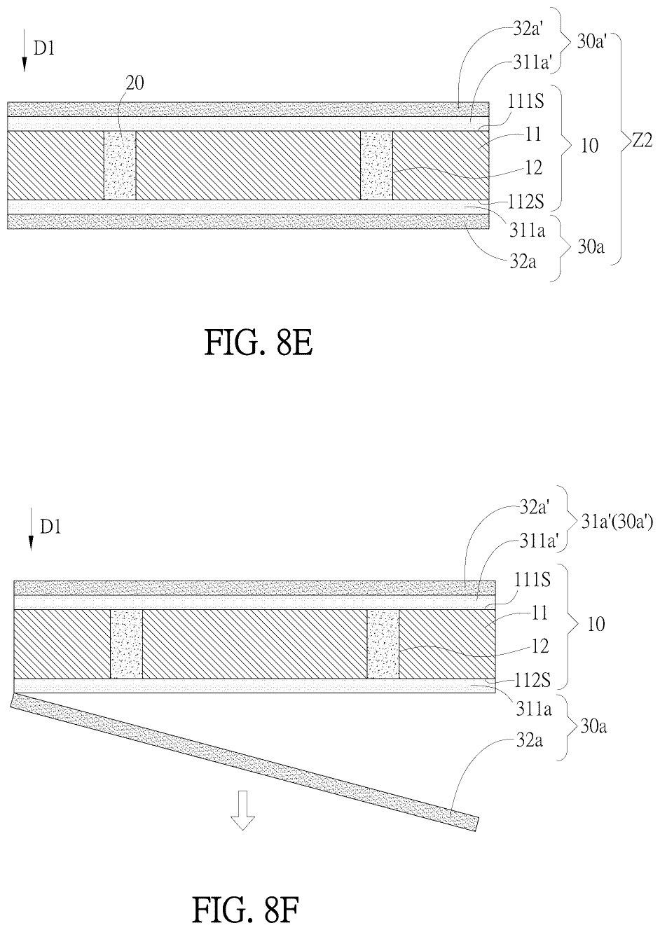

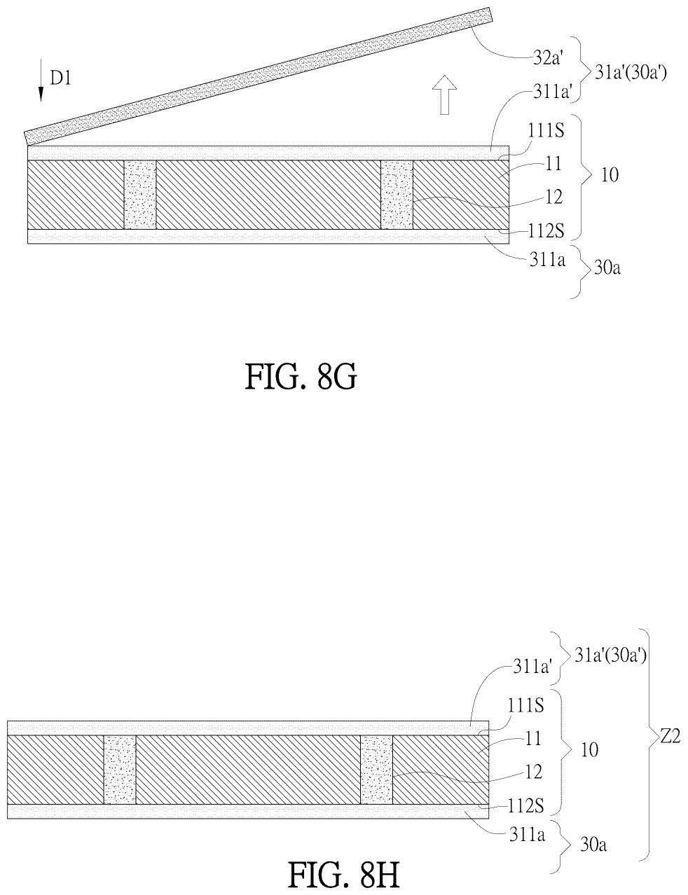

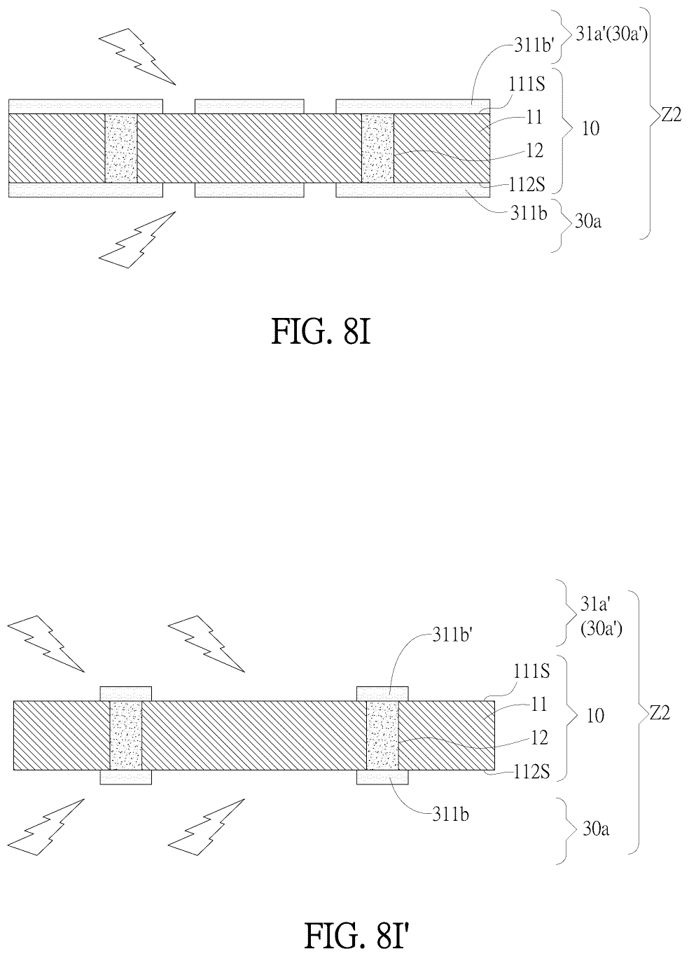

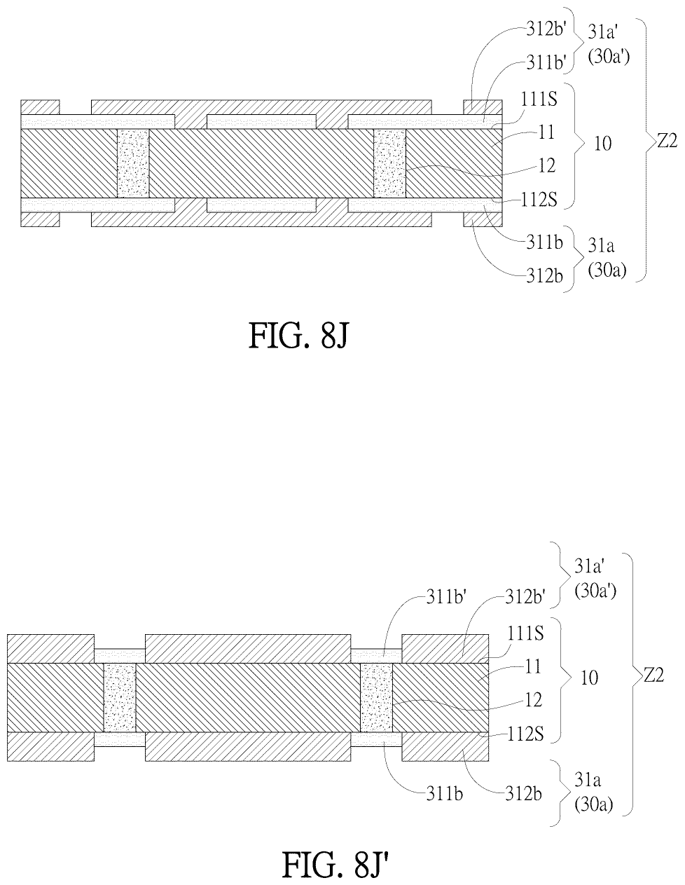

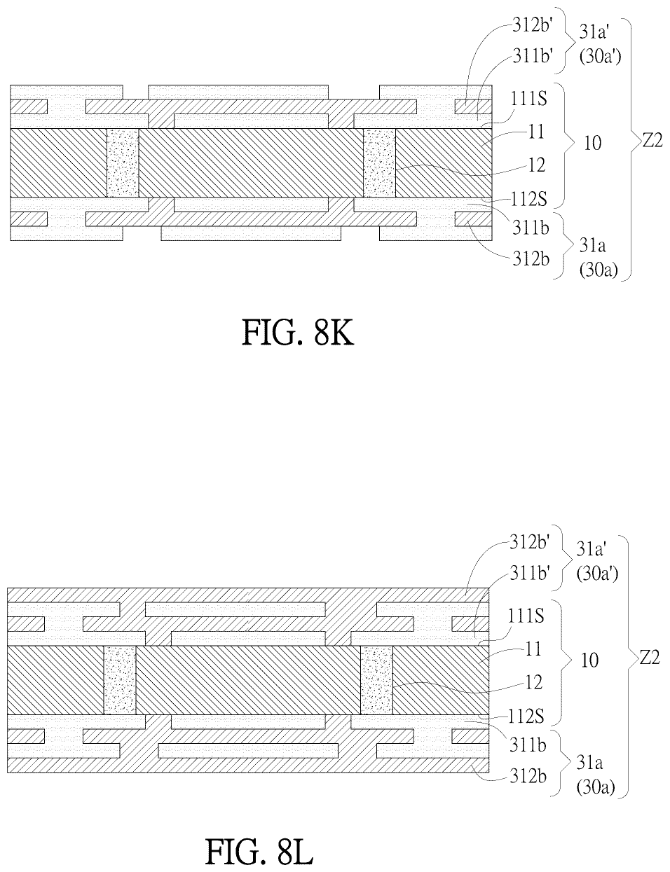

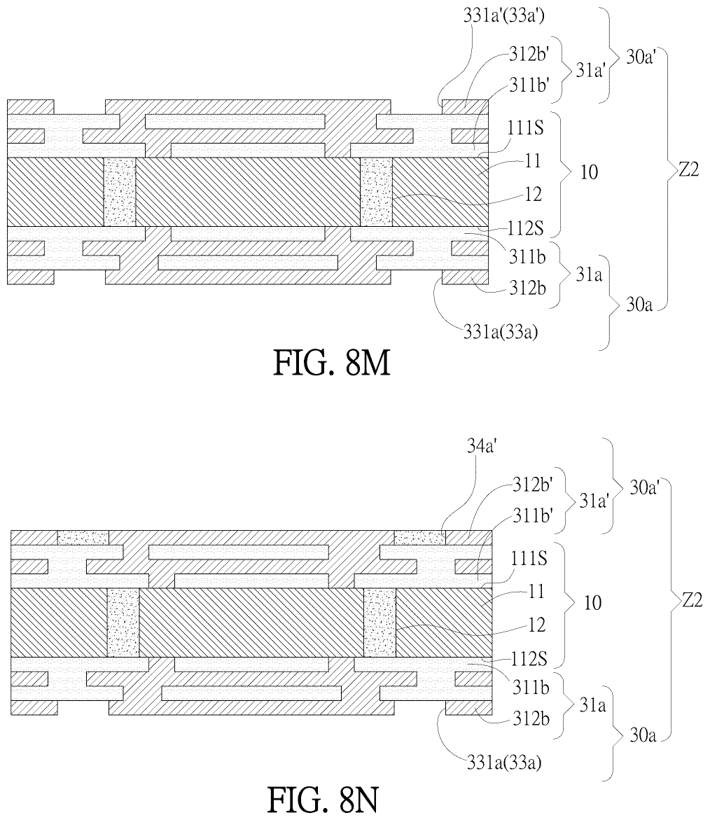

Other process variations, such as those shown in FIGS. 8A to 8M, also follow the steps described above. FIG. 8A shows a core substrate 10, which is provided with through holes 12, approaching with a conductive layer structure 30a, which includes a conducive layer 311a and a base layer 32a. FIG. 8B shows a pasting process, which is provided with a paste 83, a stencil 81 and a squeegee 82, so as to fill up the holes 12, referred in FIG. 8C. An associated conductive layer structure 30a', which includes a conducive layer 311a and a base layer 32a, is also applied to another surface of the core substrate 10, referred in FIG. 8D and FIG. 8E. To remove the base layer 32a and base layer 32a′ in FIGS. 8F and 8G, so as to get a double-sided structure Z2. The double-sided structure Z2 is further processed to form a patterned conducive layer 311b, and a patterned conducive layer 311b′, referred in FIG. 8I. An insulation layer 312b, 312b′ are provided to interwove with the patterned conducive layer 311b, 311b′, respectively, shown in FIG. 8J; to repeat the steps of FIGS. 8I and 8J so as to form semi-structures with an external linking hole 331a (33a), 331a′ (33a′) referred in FIG. 8K, FIG. 8L and FIG. 8M, and arranging the an external conductive structure 34a′ in the external linking hole 33′, shown in FIG. 8N. Alternatively, the double-sided structure Z2 is further processed the conducive layer 311b, 311b′ to form an electrode pad, referred in FIG. 8I′ and FIG. 8J′.

FIGS. 9A to 9F disclose another manufacturing method for simultaneously completing a double-sided structure, which is described previously; and the process after FIG. 9F can also refer to the patterning steps mentioned above.

What is claimed is:

1. An electronic device comprising:
a core substrate defining two surfaces opposed to each other and being provided with a through hole penetrating the two surfaces thereof, wherein a projection direction is defined as a direction perpendicular to at least one of the two surfaces of the core substrate;
a conductive layer structure stacking over one side of the core substrate; wherein the conductive pattern-layered structure at least partially covers of one opening the through hole;
an adhesive pattern layer locating between the conductive layer structure and the core substrate, and bonding the conductive layer structure to the core substrate; the adhesive pattern layer has an opening window that exposes at least a part of the conductive layer structure; wherein the through hole and the opening window overlap at least partially in the projection direction; and
a conductive member, having thermally cured conductive material, setting in the through hole of the core substrate, with one end electrically connected to the conductive layer structure through the opening window.

2. The electronic device according to claim 1, wherein the core substrate includes at least one of glass, ceramic, and glass-ceramic material.

3. The electronic device according to claim 1, wherein the core substrate defines a thermal expansion coefficient no greater than 30 ppm/° C. and no less than 17 ppm/° C.

4. The electronic device according to claim 1, wherein the conductive layer structure includes a conductive structure, and the conductive structure includes a single layer or multiple layers of conductive layers.

5. The electronic device according to claim 1, wherein the conductive member includes one or more conductive materials, wherein a volume of these conductive materials is not less than 70% of a volume of the through hole.

6. The electronic device according to claim 1, wherein the conductive member extends into the conductive layer structure.

7. The electronic device according to claim 1, wherein the adhesive pattern layer includes metal compounds or metal transitional materials.

8. The electronic device according to claim 1, wherein the conductive member has a conductive core and a conductive interlayer; the conductive core is located in the through hole, the conductive interlayer electrically connects the conductive core and the conductive layer structure; the conductive interlayer extends along the surface of the core substrate corresponding to the conductive layer structure, and is located in the opening window of the adhesive pattern layer.

9. The electronic device according to claim 1, wherein the other end of the conductive member protrudes from the other side of the core substrate.

10. The electronic device according to claim 1, further including an external conductive layer, set on the other side of the core substrate, electrically connected to the other end of the conductive member.

11. A manufacturing method for an electronic device, comprising:
forming a single-sided structure assembly; wherein the single-sided structure assembly includes:
a core substrate, having a through hole penetrating two surfaces thereof;
defining a projection direction perpendicular to one surface of the core substrate;
a conductive layer structure, stacking over one side of the core substrate, and covering at least a part of the through hole; and
an adhesive pattern layer, locating between the conductive layer structure and the core substrate, and bonding the conductive layer structure and the core substrate; wherein the adhesive pattern layer has an opening window, the opening window exposes at least a part of the conductive layer structure; wherein the through hole and the opening window at least partially overlap in the projection direction; and
arranging a conductive member in the single-sided structure assembly and further including:
arranging a conductive material in the through hole of the core substrate; and providing a thermal curing process to the conductive material to form the conductive member; wherein one end of the conductive member is electrically connected to the conductive layer structure through the opening window.

12. The manufacturing method for the electronic device according to claim 11, wherein the step of arranging the conductive member includes:
printing, spraying, or placing a conductive material into the through hole; and
providing a thermal curing process to the conductive material to form the conductive member.

13. The manufacturing method for the electronic device according to claim 11, wherein the step of forming the single-sided structure assembly includes:
preparing an undefined initial substrate;
stacking an adhesive structure onto the initial substrate; wherein the adhesive structure includes an undefined adhesive layer and a release layer; the undefined adhesive layer is located between the release layer and the initial substrate;
performing a through hole process on the initial substrate and the adhesive structure bonded thereto; wherein the initial substrate defines the through hole to form the core substrate, and the adhesive structure defines the opening window to form the adhesive pattern layer;
removing the release layer; and
attaching a conductive layer structure to the adhesive pattern layer bonded to the core substrate.

14. The manufacturing method for the electronic device according to claim 11, wherein the step of forming the single-sided structure assembly includes:
preparing the core substrate;
laying the adhesive pattern layer onto the core substrate; and
attaching the conductive layer structure to the adhesive pattern layer bonded to the core substrate.

15. The manufacturing method for the electronic device according to claim 11, wherein the step of arranging the conductive member further includes:
forming the conductive member with a conductive core and a conductive interlayer; wherein the conductive core is located in the through hole, the conductive interlayer electrically connects the conductive core and the conductive layer structure; the conductive interlayer extends along the surface of the core substrate corresponding to the conductive layer structure, and is located in the opening window of the adhesive pattern layer.

16. The manufacturing method for the electronic device according to claim 11, wherein the step of forming the single-sided structure assembly includes:
arranging an adhesive structure to the conductive layer structure; wherein the adhesive structure includes an undefined adhesive layer;
connecting the adhesive structure to the core substrate; and
before or after the step of connecting the adhesive structure and the core substrate, patterning the undefined adhesive layer to form the adhesive pattern layer.

17. The manufacturing method for the electronic device according to claim 11, wherein the step of forming the single-sided structure assembly includes:
preparing the core substrate; and
laminating the conductive layer structure to one side of the core substrate, forming the adhesive pattern layer between the core substrate or the conductive layer structure; wherein the adhesive pattern layer includes metal compounds or metal transitional materials.

18. The manufacturing method for the electronic device according to claim 11, after the step of arranging the conductive component, further including:
arranging an associate adhesive pattern layer on the other side of the core substrate, the associate adhesive pattern layer having an opening window; wherein the through hole and the opening window overlap at least partially in the projection direction; and
arranging an associate conductive layer structure, connected to the associate adhesive pattern layer, and located on the opposite side of the associate adhesive pattern layer from the core substrate;
wherein the opening window of the associate adhesive pattern layer exposes at least a part of the associate conductive layer structure, the associate conductive layer structure covers at least a part of the through hole, and the conductive component electrically connects to the associate conductive layer structure through the opening window of the associate adhesive pattern layer.

19. A manufacturing method for an electronic device, comprising:
forming a single-sided structure assembly; wherein the single-sided structure assembly includes:
a core substrate, having a through hole penetrating its two surfaces; defining a projection direction perpendicular to one surface of the core substrate;
a conductive layer structure, stacked over one side of the core substrate, and the conductive layer structure covers at least a part of the through hole; and
an adhesive pattern layer, located between the conductive layer structure and the core substrate, and bonding the conductive layer structure and the core substrate; the adhesive pattern layer having an opening window that exposes at least a part of the conductive layer structure; wherein the through hole and the opening window overlap at least partially in the projection direction;
arranging a conductive material in the through hole of the core substrate;
arranging an associate structure on the other side of the core substrate; wherein the associate structure includes an associate adhesive pattern layer and the associate conductive layer structure, the associate conductive layer structure is connected to the associate adhesive pattern layer and is located on the opposite side of the associate adhesive pattern layer from the core substrate; the associate adhesive pattern layer has an opening window, the opening window of the associate adhesive pattern layer exposes at least a part of the associate conductive layer structure, and the associate conductive layer structure covers at least a part of the through hole; and
thermally curing the conductive material to form the conductive component; wherein one end of the conductive component electrically connects to the conductive layer structure through the opening window of the adhesive pattern layer, and the other end of the conductive component electrically connects to the associate conductive layer structure through the opening window of the associate adhesive pattern layer.

20. A manufacturing method for an electronic device, comprising:
providing an undefined initial substrate;
stacking an adhesive structure and an associate adhesive structure on opposite sides of the initial substrate; wherein the adhesive structure and the associate adhesive structure each include an undefined adhesive layer and a release layer; wherein the adhesive layer is between the release layer and the initial substrate;
performing a through hole process on the initial substrate and its bonded adhesive structure and associate adhesive structure; wherein the initial substrate defines a through hole forming a core substrate; the adhesive structure and the associate adhesive structure each define an opening window to form an adhesive pattern layer and an associate adhesive pattern layer respectively;
removing the release layer of the adhesive structure;
attaching a conductive layer structure to the adhesive pattern layer, the conductive layer structure covering at least a part of the corresponding through hole;
arranging a conductive material in the through hole;
removing the release layer of the associate adhesive structure;
arranging an associate conductive layer structure on the associate adhesive pattern layer; and
thermally curing the conductive material to form a conductive component; the conductive component passes through the corresponding opening areas and is electrically connected at both ends to the conductive layer structure and the associate conductive layer structure.
